(19) United States
(12) Patent Application Publication
(10) Pub. No.: US 2005/0106786 A1
(43) Pub. Date: May 19, 2005

(54) Method of manufacturing a semiconductor device

(76) Inventors: Bunshi Kuratomi, Kodaira (JP); Fukumi Shimizu, Tachikawa (JP); Takafumi Nishita, Iruma (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/985,945

(22) Filed: Nov. 12, 2004

(30) Foreign Application Priority Data
Nov. 14, 2003 (JP) 2003-385027

(51) Int. Cl. H01L 21/44; H01L 21/48; H01L 21/50; H01L 23/48; H01L 23/52; H01L 29/40

(52) U.S. Cl. 438/127

(57) ABSTRACT

The delivery times of semiconductor devices are shortened. The upper die of a mold is provided with an opening which runs from the outside surface of the upper die to the cavity. A movable cavity piece is installed by fitting the movable cavity piece into the opening so that the movable cavity piece can be moved up and down. In the molding process, the height of the lower face of the movable cavity piece is adjusted in accordance with the thickness of a blanket sealing body, and then sealing resin is injected into the cavity. Thus, a change in the thickness of the blanket sealing body can be easily coped with in a short time. After molding, the movable cavity piece is moved up and separated from the blanket sealing body, and thereby mold release is carried out.

### CROSS-REFERENCE TO RELATED APPLICATION

The present application claims priority from Japanese patent application No. 2003-385027, filed on Nov. 14, 2003, the content of which is hereby incorporated by reference into this application.

### BACKGROUND OF THE INVENTION

The present invention relates to a manufacturing technique for semiconductor devices, and more particularly to a molding technique wherein electronic components, such as semiconductor chips, mounted over a circuit board are sealed with resin.

Recently, semiconductor device products have been increasingly diversified. Because of this and the like, molding processes for semiconductor devices confront a problem: the thickness of resin sealing bodies for sealing semiconductor chips and the thickness of circuit boards mounted with semiconductor chips vary. Therefore, molds for molding resin sealing bodies must be changed in accordance with variation in these thicknesses. This leads to the increased development cost and manufacturing cost and the lengthened development period of semiconductor devices. As a measure to cope with this problem, for example, Japanese Unexamined Patent Publication No. 2000-286278 discloses the following technique: a detachable block is provided on the bottom face of the cavity in the lower die of a mold in tight contact with the bottom face. Variation in the thickness of resin sealing bodies is coped with by replacing the detachable block. (Refer to Patent Document 1.)

[Patent Document 1] Japanese Unexamined Patent Publication No. 2000-286278

### SUMMARY OF THE INVENTION

However, the above-mentioned technique wherein a detachable block is provided in a cavity has a problem: each time the thickness of the resin sealing body for semiconductor devices is varied, the mold must be dismantled to replace the detachable block with another. This work is cumbersome and takes a lot of trouble and time. As a result, the development periods and manufacturing times for semiconductor devices are lengthened, and this hinders shortening of the delivery times of semiconductor devices.

An object of the present invention is to provide a technique that allows the delivery times of semiconductor devices to be shortened.

This and other objects of the present invention will become apparent from the description in this application and the accompanying drawings.

The following is a brief description of the gist of the representative elements of the invention laid open in this application.

More specific description will be given. The present invention comprises the following step preceding a step in which the cavities in a mold are filled with sealing resin to form a sealing body: a step in which the amount of movement of a movable block which is installed in an opening formed in the upper die of the mold so that the movable block is movable in the direction intersecting the molding surface of the upper die is adjusted in accordance with the thickness requirement for the sealing body.

Further, the present invention comprises the step of releasing the sealing body from the mold after the sealing body is formed by filling the cavities in the mold with sealing resin. In this releasing step, the peripheral portion of the product area of the sealing body and a substrate having the sealing body formed thereover are clamped between the upper die and the lower die of the mold. The movable block installed in the opening formed in the upper die so that the movable block is movable in the direction intersecting the molding surface of the upper die is moved up and thereby released from the sealing body.

The following is a brief description of the gist of the effects obtained by the representative elements of the invention laid open in this application.

Variation in the thickness of the resin sealing body of semiconductor devices can be easily coped with in a short time; therefore, the delivery times of semiconductor devices can be shortened.

### BRIEF DESCRIPTION OF THE DRAWINGS

FIG. 1 is a general plan view of the element placement face of a circuit board substrate used in the method of manufacturing a semiconductor device as an embodiment of the present invention.

FIG. 2 is a side view of FIG. 1.

FIG. 3 is an enlarged cross-sectional view taken along the line X1-X1 of FIG. 1.

FIG. 4 is a general plan view of the circuit board substrate after semiconductor chips are mounted on the element placement face of the circuit board substrate in FIG. 1.

FIG. 5 is a side view of the circuit board substrate in FIG. 4.

FIG. 6 is an explanatory drawing of the molding process for semiconductor devices, succeeding FIG. 4 and FIG. 5.

FIG. 7 is an explanatory drawing of the molding process for semiconductor devices, succeeding FIG. 6.

FIG. 8 is an explanatory drawing of the molding process for semiconductor devices, succeeding FIG. 7.

FIG. 9 is an explanatory drawing of the resin injection step in the molding process for semiconductor devices, succeeding FIG. 8.

FIG. 10 is an explanatory drawing of the mold release step in the molding process for semiconductor devices, succeeding FIG. 9.

FIG. 11 is an explanatory drawing of the mold release step in the molding process for semiconductor devices, succeeding FIG. 10.

FIG. 12 is an explanatory drawing of the mold release step in the molding process for semiconductor devices, succeeding FIG. 11.

FIG. 13 is a perspective view of the circuit board substrate released from the mold after the steps in FIG. 1 to FIG. 12.

FIG. 14 is a general plan view of the circuit board substrate in FIG. 13 on the element placement face side.

FIG. 15 is an explanatory drawing of the solder bump bonding step for semiconductor devices, succeeding FIG. 12.

FIG. 16 is an explanatory drawing of the solder bump bonding step for semiconductor devices, succeeding FIG. 15.

FIG. 17 is an explanatory drawing of the cutting step for semiconductor devices in which the circuit board substrate and the sealing body are cut in a lump, succeeding FIG. 16.

FIG. 18 is a perspective view of a semiconductor device in the embodiment of the present invention.

FIG. 19 is a side view illustrating the semiconductor device in FIG. 18 part of which is ruptured.

FIG. 20 is an explanatory drawing of an example of automatic molding equipment used in the method for manufacturing a semiconductor device in the embodiment of the present invention.

FIG. 21 is a plan view illustrating the lower die and upper die of a mold on the automatic molding equipment in FIG. 20 as are superposed together.

FIG. 22 is a plan view of the molding surface of the lower die of the mold on the automatic molding equipment in FIG. 20.

FIG. 23 is a plan view of the molding surface of the lower die in FIG. 22 with a circuit board substrate placed on its molding surface.

FIG. 24 is a plan view of the molding surface of the upper die of the mold on the automatic molding equipment in FIG. 20.

FIG. 25 is a plan view of the molding surface of the upper die in FIG. 24, illustrating the positional relationship between the upper die and the circuit board substrate.

FIG. 26 is a cross-sectional view taken along the line X2-X2 of FIG. 21.

FIG. 27 is an enlarged cross-sectional view of area B in FIG. 26.

FIG. 28 is an enlarged cross-sectional view of area C in FIG. 26.

FIG. 29 is an enlarged cross-sectional view of area D in FIG. 26.

FIG. 30 is a cross-sectional view taken along the line X3-X3 of FIG. 21.

FIG. 31 is a cross-sectional view taken along the line X4-X4 of FIG. 21.

FIG. 32 is an enlarged plan view of area E in FIG. 21.

FIG. 33 is a cross-sectional view of the mold on the automatic molding equipment explained in connection with FIG. 21 to FIG. 32, illustrating its portion corresponding to the line X2-X2 of FIG. 21 in the molding process.

FIG. 34 is a cross-sectional view of the mold in the molding process, succeeding FIG. 33.

FIG. 35 is a cross-sectional view of the mold at area M in FIG. 34.

FIG. 36 is a cross-sectional view illustrating the portion corresponding to the line X3-X3 of FIG. 21 in the molding process illustrated in FIG. 34.

FIG. 37 is a cross-sectional view of the portion corresponding to the line X4-X4 of FIG. 21 in the molding process illustrated in FIG. 34.

FIG. 38 is a cross-sectional view of the mold in the molding process, succeeding FIG. 34 to FIG. 37.

FIG. 39 is a cross-sectional view of the mold in the molding process, succeeding FIG. 38.

FIG. 40 is a cross-sectional view of the mold in the molding process, succeeding FIG. 39.

FIG. 41 is a cross-sectional view of the mold in the molding process, succeeding FIG. 40.

FIG. 42 is an explanatory drawing of the molding process in the method of manufacturing a semiconductor device in another embodiment of the present invention.

FIG. 43 is an explanatory drawing of the molding process, succeeding FIG. 42.

FIG. 44 is an explanatory drawing of the molding process, succeeding FIG. 43.

FIG. 45 is an explanatory drawing of the molding process, succeeding FIG. 44.

FIG. 46 is an explanatory drawing of the molding process, succeeding FIG. 45.

FIG. 47 is an explanatory drawing of the molding process, succeeding FIG. 46.

FIG. 48 is a perspective view of an example of the circuit board substrate released from the mold after the steps in FIG. 42 to FIG. 47.

### DETAILED DESCRIPTION OF THE PREFERRED EMBODIMENTS

In the following description of the present invention, it will be divided into a plurality of sections or embodiments if necessary for the sake of convenience. However, they are not regardless of each another, and are in such relation that one is a modification to, the details of, the supplementary explanation of, or the like of part or all of the other unless otherwise stated. If reference is made to any number of elements or the like (including number of pieces, numeric value, quantity, range, and the like) in the description of the embodiments below, the present invention is not limited by that value. The number may be greater or less than the value. However, the following cases are excepted: cases where some number is explicitly specified, cases where some number is evidently limited to a specific value in principle, and the like. Needless to add, in the embodiments described below, their components (including constituent steps and the like) are not necessarily indispensable excepting the following cases: cases where some component is explicitly specified, cases where some component is evidently indispensable in principle, and the like. Similarly, if reference is made to the shape, positional relationship, or the like of any component or the like in the description of the embodiments below, those substantially approximate or analogous to that shape or the like are included. However, the following cases are excepted: cases where difference in shape or the like is explicitly stated, cases where some shape or the like is evidently considered not to be approximate or analogous in principle, and the like. This is the same with the above-mentioned numeric values and ranges. In all the drawings for the explanation of the embodiments, the members having identical functions will be marked with identical numerals, and their repetitive description will be omitted. Embodiments of the present invention will be described in detail below, referring to the drawings.

### First Embodiment

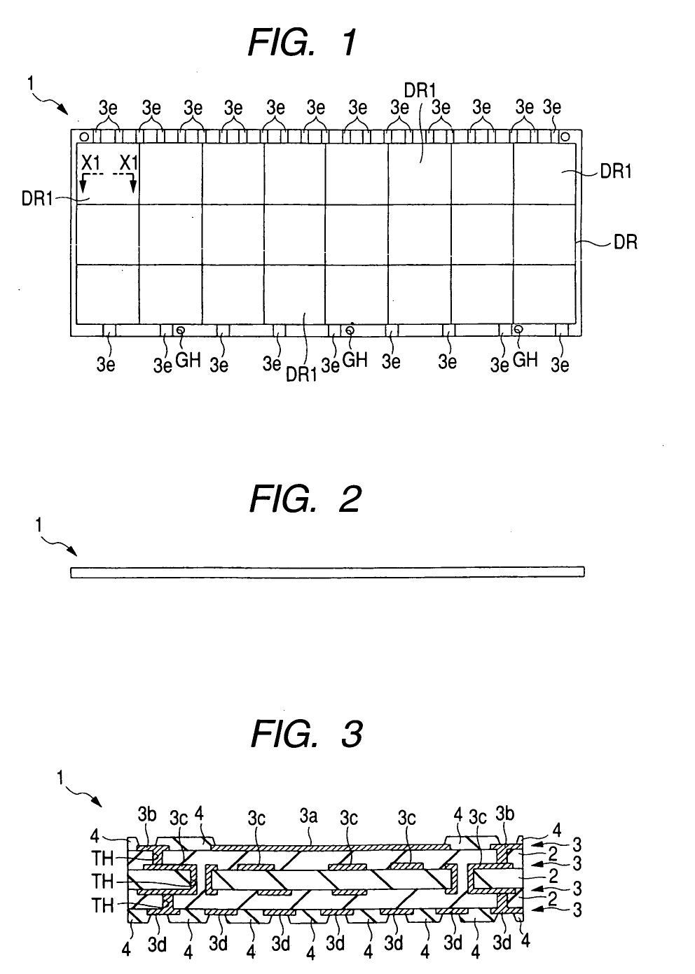

The first embodiment is implemented by applying the present invention to a MAP (Mold Array Package) method of manufacturing a semiconductor device. The MAP is a method wherein, for example, a plurality of semiconductor chips mounted over circuit boards are sealed in a lump. The first embodiment will be described referring to FIG. 1 to FIG. 19.

First, a circuit board substrate (hereafter, referred to as “board substrate”) 1 illustrated in FIG. 1 to FIG. 3 is prepared. FIG. 1 is a general plan view of the element placement face of the board substrate 1; FIG. 2 is a side view of the board substrate 1 in FIG. 1; and FIG. 3 is an enlarged cross-sectional view taken along the line X1-X1 of FIG. 1.

The board substrate 1 is a substrate for the circuit boards of semiconductor devices described later, and with respect to appearance, the board substrate 1 is, for example, of a flat rectangular thin plate. The board substrate 1 has a principal surface and a rear face positioned opposite thereto. The principal surface of the board substrate 1 is an element placement face to be mounted with semiconductor chips (hereafter, referred to as “chip”) as described later. The rear face of the board substrate 1 is a bump electrode formation face on which bump electrodes are formed as described later. A product area DR is disposed on the board substrate 1. In the product area DR, a plurality of unit product areas DR1, identical in dimensions and shape, are disposed adjacently in the vertical and horizontal directions in FIG. 1. Each unit product area DR1 is a unit area having a circuit board constitution required for forming one semiconductor device. A plurality of guide holes GH which runs from the principal surface to the rear face of the board substrate 1 are formed in proximity to either long side of the periphery of the board substrate 1. By inserting the guide pins of the mold, described later, into the guide holes GH, the board substrate 1 can be placed on the lower die in alignment with the lower die.

The board substrate 1 has multilayer interconnection structure. FIG. 3 illustrates an example of four-layered interconnection constitution. In FIG. 3, the upper face of the board substrate 1 is the above-mentioned element placement face, and the lower face of the board substrate 1 is the above-mentioned bump electrode formation face. The board substrate 1 comprises: a laminate formed by alternately stacking insulating base materials (core materials) 2 and wiring layers 3; and solder resist 4 applied to the upper and lower faces (element placement face and bump electrode formation face) of the laminate. The insulating base material 2 is composed of, for example, glass epoxy resin highly resistant to heat. The material of the insulating base material 2 is not limited to this, and a variety of materials can be used therefor. For example, BT resin, aramid nonwoven fabric material, or the like may be used. If BT resin is selected for the material of the insulating base material 2, the heat radiating property can be enhanced because of its high thermal conductivity.

Various conductor patterns 3a to 3e are formed in each wiring layer 3 of the board substrate 1. The conductor patterns 3a to 3e are obtained, for example, by etching copper (Cu) foil. The purposes of the conductor patterns in the wiring layer 3 containing the element placement face are as follows: the conductor pattern 3a is a pattern for mounting a chip; the conductor pattern 3b is an electrode pattern to which bonding wires are connected; and the conductor pattern 3e is a pattern for making it easier to strip the resin for sealing, described later. In addition, conductor patterns for signal wiring and power supply wiring are formed in the wiring layer 3 containing the element placement face. Portions of the conductor patterns 3a, 3b, and 3e and the like on the element placement face are exposed from the solder resist 4, and the exposed surfaces are plated with, for example, nickel (Ni) or gold (Au) . The conductor pattern 3d in the wiring layer 3 containing the bump electrode formation face is an electrode pattern for joining bump electrodes. In addition, conductor patterns for signal wiring and power supply wiring are formed also in the wiring layer 3 containing the bump electrode formation face. Portions of the conductor pattern 3d and the like on the bump electrode formation face are also exposed from the solder resist 4, and their exposed surfaces are plated with nickel or gold. The conductor patterns 3c in the wiring layers 3 inside the above-mentioned laminate are wiring patterns for signals and power supply. The individual wiring layers 3 are electrically connected with one another through the conductor (copper foil or the like) in through holes TH. The above solder resist 4 is also designated as solder mask or stop-off, and is provided with the following functions: the function of preventing molten solder from being brought into, contact with conductor patterns in no need of soldering during soldering; the function as a protective film which protects conductor patterns out of soldering areas from molten solder; the functions of preventing solder bridges between conductors, providing protection against contamination and humidity, preventing damage, providing environmental resistance, preventing migration, maintaining insulation between circuits, preventing short-circuiting between a circuit and other components (chips, printed-circuit boards, and the like) ; and the like. The solder resist 4 is composed of, for example, polyimide resin, and is applied in specific areas on the principal surface and the rear face of the board substrate 1.

As an example, the board substrate 1 of four-layered interconnection structure is taken here. However, the present invention is not limited to this constitution, and board substrates 1 of various wiring layer constitutions (various product types) flow into the molding process for semiconductor devices on a lot-by-lot basis. Such board substrates include board substrates 1 of two-layered interconnection structure, less than four layers, and board substrates 1 of six-layered interconnection structure, more than four layers. When the number of wiring layers (product type) differs, the thickness of the board substrate 1 differs as well. (In the present situation, the thickness varies within the range of, for example, 210 to 1000 μm or so.) In addition, in case of the board substrate 1 of multilayer interconnection structure, the thickness of board substrate 1 varies within the range of error even if the number of wiring layers is the same. (In the present situation, the thickness varies within the range of, for example, ±30 μm or so.) Recently, the number of wiring layers has been more and more increased, and errors in thickness have been also increased. Therefore, how flexibly change in the thickness of board substrates 1 should be coped with presents a significant challenge for molding processes.

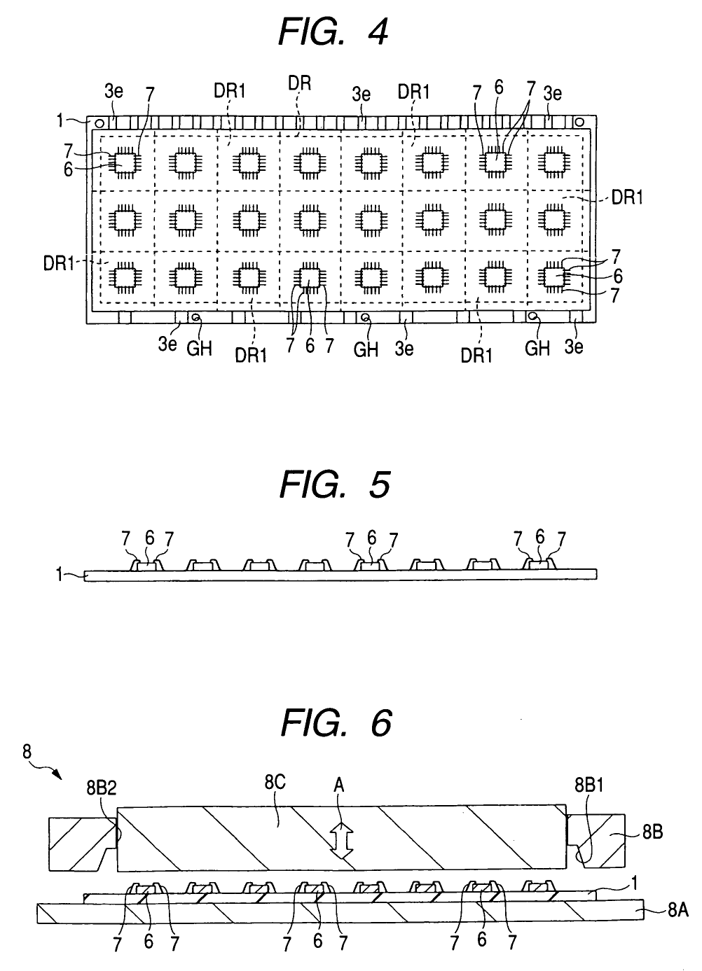

As illustrated in FIG. 4 and FIG. 5, subsequently, a chip 6 is mounted in each unit product area DR1 on the element placement face of the board substrate 1, using such adhesive as paste containing silver. There is no special limitation on the thickness of the chip 6, but it is, for example, approximately 100 μm or below. Subsequently, the wire bonding step is carried out using a publicly known wire bonder using, for example, ultrasonic vibration and thermo-compression bonding together. In this step, the bonding pads of the chip 6 and the conductor pattern 3b on the element placement face of the board substrate 1 are electrically connected with each other through a bonding wire 7 composed of, for example, gold. FIG. 4 is a general plan view illustrating the element placement face of the board substrate 1 after the wire bonding step, and FIG. 5 is a side view of the board substrate 1 in FIG. 4. The case where one chip 6 is mounted in each unit product area DR1 is described here as an example, but the present invention is not limited to this constitution. For example, a plurality of chips 6 may be mounted in each unit product area DR1 in a line, or a laminated chip obtained by laminating a plurality of chips 6 may be mounted in each unit product area DR1. Various board substrates 1, different in the thickness of the chip 6 or the height of the bonding wires 7, flow into the molding process for semiconductor devices. In addition, the board substrates 1 with each unit product area DR1 mounted with one chip 6 and the board substrates 1 with each unit product area DR1 mounted with the above laminated chip flow into the process sometimes. For this reason, there are cases where the thickness of a sealing body for sealing the chip 6, described later, must be varied in accordance with this variation. Therefore, not only coping with variation in the thickness of the board substrate 1, described above, but also how flexibly change in the thickness of the sealing body should be coped with presents a significant challenge for molding processes.

As illustrated in FIG. 6, subsequently, the board substrate 1 which underwent the above wire bonding step is transported to the mold 8 and is placed on the lower die 8A of the mold 8. At this time, the guide pins of the lower die 8A are inserted into the guide holes GH in the board substrate 1, and thereby the board substrate 1 is aligned with the lower die 8A. The mold 8 in the first embodiment comprises a lower die (first die) 8A, an upper die (second die) 8B, and a movable cavity piece (movable block) 8C. The recess in the molding surface (surface opposed to the lower die 8A) of the upper die 8B is upper die cavity 8B1. The upper die cavity 8B1 is the sealing resin molding area on the upper die 8B side. The upper die cavity 8B1 is so formed that it is sufficiently large to seal a plurality of chips 6 on the board substrate 1 in a lump. In the description of the first embodiment, the various portions of the surface of the upper die 8B will be respectively designated as follows for the sake of convenience: the portion of the surface other than the upper die cavity 8B1 is designated as non-cavity surface; the portion of the non-cavity surface opposed to the lower die 8A is designated as lower die opposed surface; and the surface opposite the lower die opposed surface is designated as outside surface. An opening 8B2 running from the outside surface to the upper die cavity 8B1 is formed in the upper die 8B. The movable cavity piece 8C is fit into this opening 8B2 so that the movable cavity piece 8C is movable in the direction indicated by arrow A, orthogonal to the lower die opposed surface (molding surface). The movable cavity piece 8C is a component for setting the depth of the cavity in the upper die 8B, that is, the thickness of the above-mentioned sealing body. The substantial cavity in the upper die 8B is formed by the upper die cavity 8B1 and the movable cavity piece 8C. The movable cavity piece 8C is so constituted that the size of its lower face (molding surface: surface opposed to the lower die 8A) is equal to or larger than the size of the product area DR and smaller than the circumference of the bottom face of the recess (upper face of the cavity) of the upper die cavity 8B1. An example of the constitution of the mold 8 will be described in detail later.

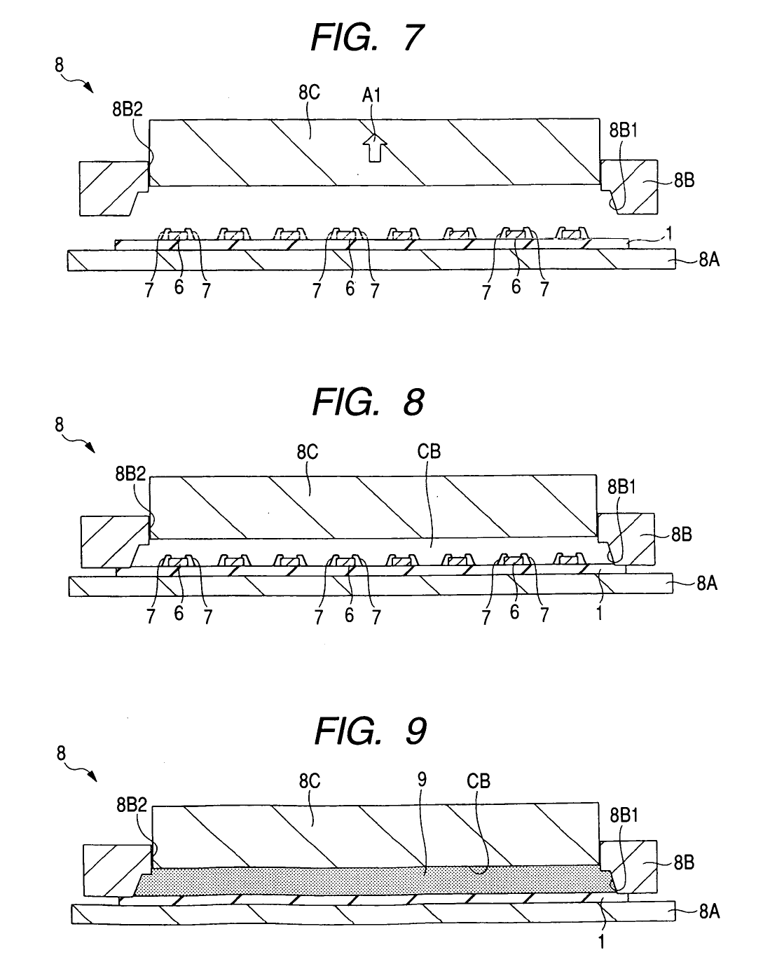

Next, the molding process using this mold 8 will be described. First, with the temperature of the lower die 8A kept at, for example, 175 to 180° C. or so, the board substrate 1 is preheated for 20 seconds or so. This preheating is carried out for settling deformation in the board substrate 1 due to heat, and other like purposes. As illustrated in FIG. 7, subsequently, the movable cavity piece 8C is moved up in the direction indicated by arrow A1 to form the substantial cavity in the upper die 8B. At this time, in the first embodiment, the thickness of the sealing body can be set as desired by adjusting the distance of vertical movement of the movable cavity piece 8C. At present, a mold is fabricated each time the thickness of the sealing body is changed. Therefore, the work for coping with variation in the thickness of the sealing body is cumbersome and takes a lot of time and manpower. In the first embodiment, meanwhile, variation in the thickness of the sealing body can be coped with just by adjusting the distance of vertical movement of the movable cavity piece 8C. Therefore, variation in the thickness of the sealing body can be easily coped with in a short time. As a result, the delivery times of semiconductor devices can be shortened. Further, in the first embodiment, the accuracy of formation of the thickness of the sealing body can be enhanced. In case of ordinary molds without the movable cavity piece 8C, the accuracy of formation of the thickness of the sealing body is determined by die machining accuracy, and its range of error is ±20 μm or so. In the first embodiment, meanwhile, the range of error in the thickness of the sealing body can be reduced to approximately ±5 μm or below. As a result, the accuracy of formation of the thickness of the sealing body can be enhanced. Further, in the first embodiment, variation in the thickness of the sealing body can be coped with by a single mold. Thus, it becomes unnecessary to purchase a new mold when the thickness of the sealing body is changed, and jig and tooling costs can be reduced. In addition, existing molding facilities can be used, and initial investments can be reduced. As a result, the development costs and manufacturing costs of semiconductor devices can be reduced. Here, the case where the position of the lower face of the movable cavity piece 8C is higher than the bottom face of the recess of the upper die cavity 8B1 is described as an example. As illustrated in FIG. 8, thereafter, the board substrate 1 is clamped and held between the upper die 8B and the lower die 8A. At this time, the peripheral portion of the board substrate 1 is pressed against the lower die opposed surface of the peripheral portion of the cavity 8B1 in the upper die 8B. Thus, the peripheral portion of the board substrate 1 is crushed by 5% or so of the total thickness of the board substrate 1. Thus, the cavity CB encircled with the upper die cavity 8B1, movable cavity piece 8C, and board substrate 1 is formed.

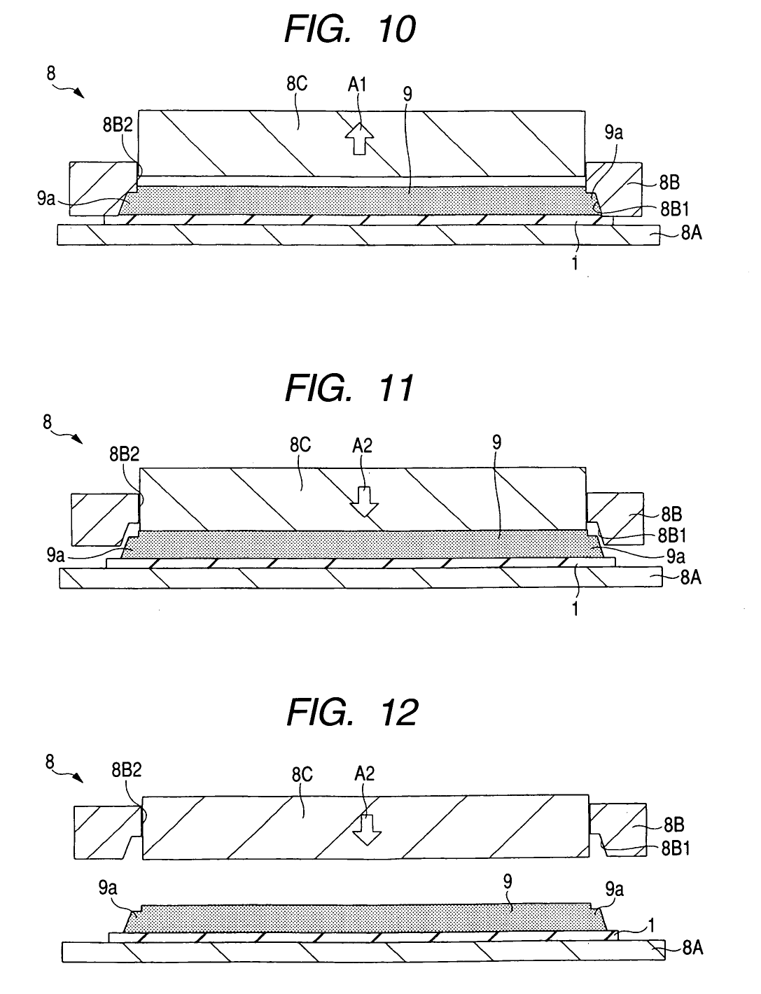

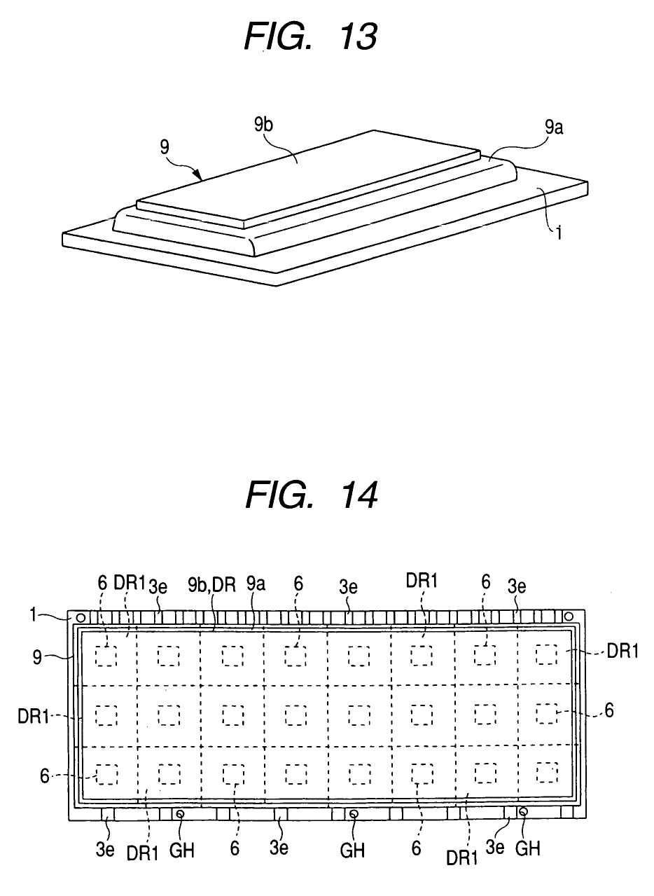

Subsequently, with the above-mentioned temperature maintained, thermosetting sealing resin, such as epoxy resin, is poured into the cavity CB. Thereby, a plurality of the chips 6, bonding wires 7, and the like on the principal surface of the board substrate 1 are sealed in a lump. Thus, the blanket sealing body 9 involving a plurality of the chips 6 is molded over the board substrate 1 on the principal surface side, as illustrated in FIG. 9. In the figure, the blanket sealing body 9 is hatched to make the figure easy to view. After the sealing resin has been cured, the board substrate 1 with the blanket sealing body 9 molded thereover is released from the mold 8. In the first embodiment, the following procedure is taken at this time: with the above-mentioned temperature of the lower die 8A maintained, the lower die 8A and the upper die 8B are kept in fixed state (i.e. state in which the mold 8 is closed). In this state, as illustrated in FIG. 10, the movable cavity piece 8C is moved up in the direction indicated by arrow A1 to separate the lower face of the movable cavity piece 8C from the blanket sealing body 9. At this time, the upper die 8B firmly holds down the peripheral portion of the element placement face of the board substrate 1 and the peripheral portion (shoulder) 9a of the upper face of the blanket sealing body 9 in a balanced manner. Therefore, the movable cavity piece 8C can be easily broken away from the blanket sealing body 9 without damaging the blanket sealing body 9. That is, the releasability between the upper die 8B and the blanket sealing body 9 can be enhanced. Further, when the blanket sealing body 9 is released from the mold, force for mold release is not exerted directly on the chips 6, chip crack failure can be prevented. As a result, the yield and the reliability of semiconductor devices can be enhanced. As illustrated in FIG. 11, subsequently, the lower die 8A and the upper die 8B are separated from each other. At the same time, the movable cavity piece BC is pressed down in the direction indicated by arrow A2 to push the board substrate 1 out of the upper die cavity 8B1. Thus, the board substrate 1 is completely released from the upper die 8B, as illustrated in FIG. 12. FIG. 13 is a perspective view of the board substrate 1 after the above-mentioned mold release, and FIG. 14 is an general plan view of the board substrate 1 in FIG. 13 on the element placement face side. In this case, a projected portion 9b is formed in the center of the upper face of the blanket sealing body 9 so that the projected portion 9b is protruded upward from the peripheral portion 9a level. The size of the flat face of the projected portion 9b is equal to or slightly larger than the size of the product area DR. The upper face of the projected portion 9b is flat.

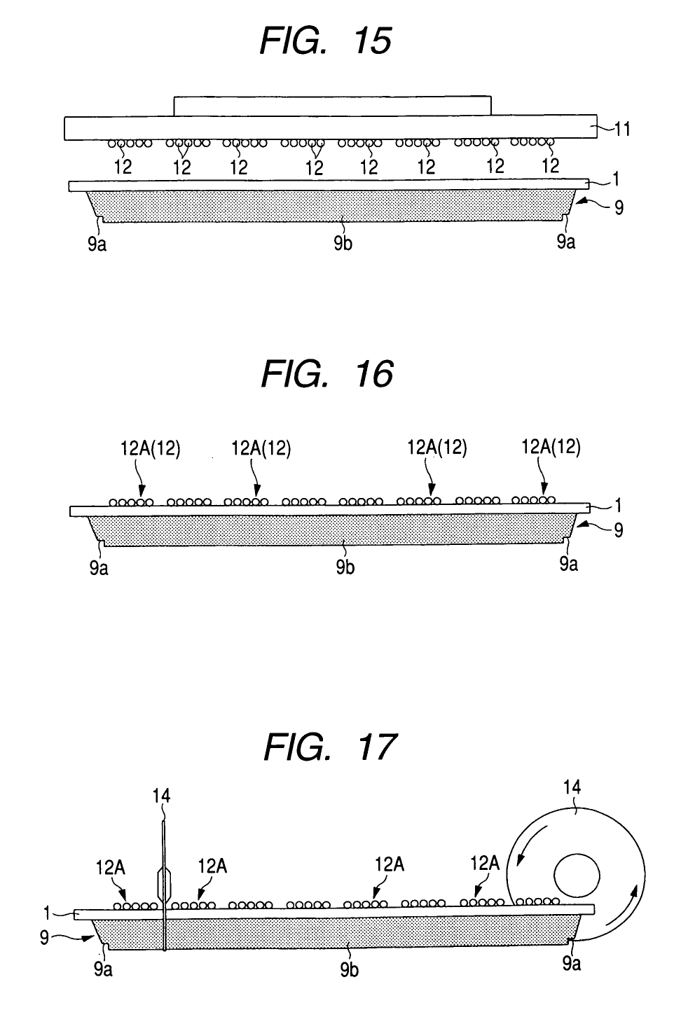

Next, the solder bump bonding step will be described. First, as illustrated in FIG. 15, a plurality of spherical solder bumps 12 held by a bump holding tool 11 are immersed in a flux bath to apply flux to the surfaces of the solder bumps 12. Thereafter, a plurality of the solder bumps 12 are simultaneously and temporarily bonded to the conductor pattern 3d on the bump electrode formation face of the board substrate 1, utilizing the adhesion of the flux. The solder bump 12 is composed of, for example, lead (Pb)/tin (Sn) solder. For the material of the solder bump 12, lead-free solder, such as tin/silver (Ag) solder, may be used. The solder bumps 12 may be joined in a lump to each unit product area DR1. From the viewpoint of the enhancement of throughput of the solder bump bonding step, it is preferable that the solder bumps 12 should be joined in a lump to a plurality of unit product areas DR1. Subsequently, the solder bumps 12 are subjected to heating reflow at a temperature of, for example, 220° C. or so, and are thereby bonded to the conductor pattern 3d to from bump electrodes 12A, as illustrated in FIG. 16. Thereafter, residual flux and the like remaining on the surface of the board substrate 1 are removed using neutral detergent or the like, and thereby the solder bump bonding step is completed.

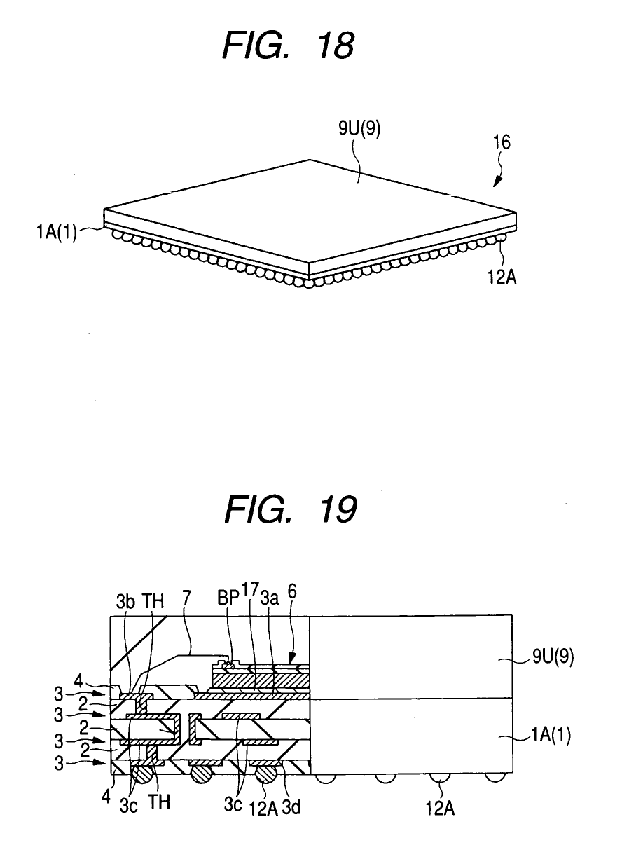

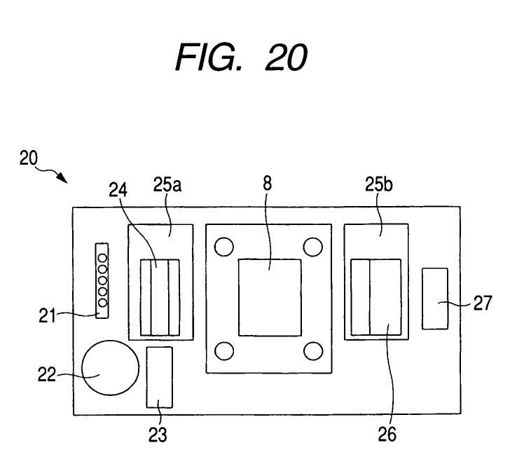

Next, the board substrate 1 is turned upside down, and the blanket sealing body 9 on the element placement face side of the board substrate 1 is fixed by an adhesive tape or the like. In the first embodiment, the upper face of the blanket sealing body 9 to which an adhesive tape or the like is stuck is stepped. However, the upper face of the projected portion 9b which constitutes the majority of the upper face of the blanket sealing body 9 is free from steps and flat. Therefore, the blanket sealing body 9 can be firmly fixed by an adhesive tape or the like. As illustrated in FIG. 17, subsequently, the board substrate 1 and the blanket sealing body 9 are cut from the rear face of the board substrate 1, using a dicing blade 14 just like dicing. Thus, as illustrated in FIG. 18 and FIG. 19, a plurality of semiconductor devices 16 of, for example, CSP (Chip Size Package) type are simultaneously obtained. FIG. 18 is a perspective view of an example of the thus obtained semiconductor device 16, and FIG. 19 is a side view of the semiconductor device 16 in FIG. 18 part of which is ruptured. The circuit board 1A is a member obtained by cutting the above-mentioned board substrate 1. The conductor pattern 3a on the element placement face of the circuit board 1A is mounted with the chip 6 with its principal surface facing upward, using such adhesive 17 as paste containing silver. The above-mentioned bonding pads BP on the principal surface of the chip 6 are electrically connected with the conductor pattern 3b on the element placement face of the circuit board 1A through the above-mentioned bonding wires 7. A sealing body 9U is molded over the element placement face of the circuit board 1A, and the chip 6 and the bonding wires 7 are sealed with this sealing body 9U. The sealing body 9U is a member obtained by cutting the above-mentioned blanket sealing body 9, and its thickness is, for example, approximately 500 μm or below. Meanwhile, the conductor pattern 3d on the bump electrode formation face of the circuit board 1A is connected with the bump electrodes 12A. The conductor pattern 3a and the like on the element placement face are electrically connected with the conductor pattern 3d and the bump electrodes 12A on the bump electrode formation face. They are electrically connected with each other through the conductor pattern 3c of the circuit board 1A and the through holes TH.

Next, description will be given to molding equipment having the above-mentioned mold 8.

FIG. 20 is an explanatory drawing of an example of automatic molding equipment 20. The automatic molding equipment 20 comprises a tablet alignment unit 21, a tablet parts feeder 22, a substrate loader 23, a substrate alignment unit 24, a carry-in transport unit 25a, a mold 8, a gate break unit 26, a carry-out transport unit 25b, and an unloader 27. Board substrates 1 which underwent the above-mentioned wire bonding step and have not been molded yet are placed in the automatic molding equipment 20 through the substrate loader 23. The board substrates 1 are aligned at the substrate alignment unit 24, and thereafter placed on the lower die of the mold 8 through the carry-in transport unit 25a. Each board substrate 1 undergoes the molding process with the mold 8, and residual resin at the sealing resin injection ports is removed by the gate break unit 26. Thereafter, the board substrate 1 is transported to the unloader 27 through the carry-out transport unit 25b, and is taken out by the unloader 27. At the substrate loader 23, substrate alignment unit 24, or carry-in transport unit 25a, the thickness of board substrates 1 can be measured. The thickness of board substrates 1 is obtained as follows: the board substrate 1 is placed flat, and the thickness of the board substrate 1 is mechanically or optically measured at four to ten points on the principal surface of the board substrate 1. Thereafter, a plurality of measured values are averaged to determine the thickness.

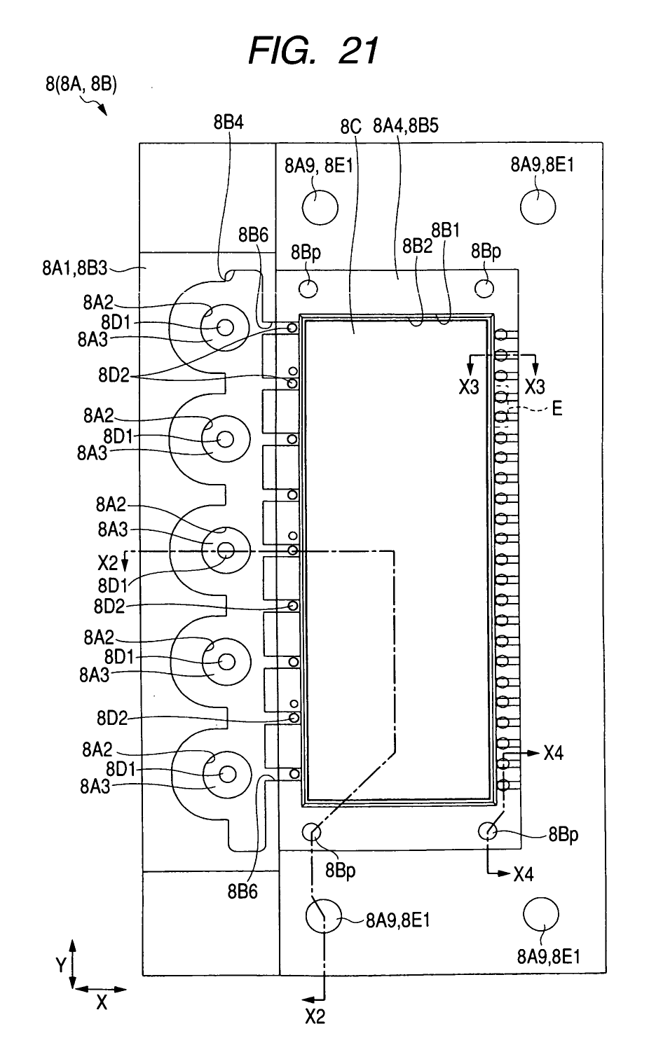

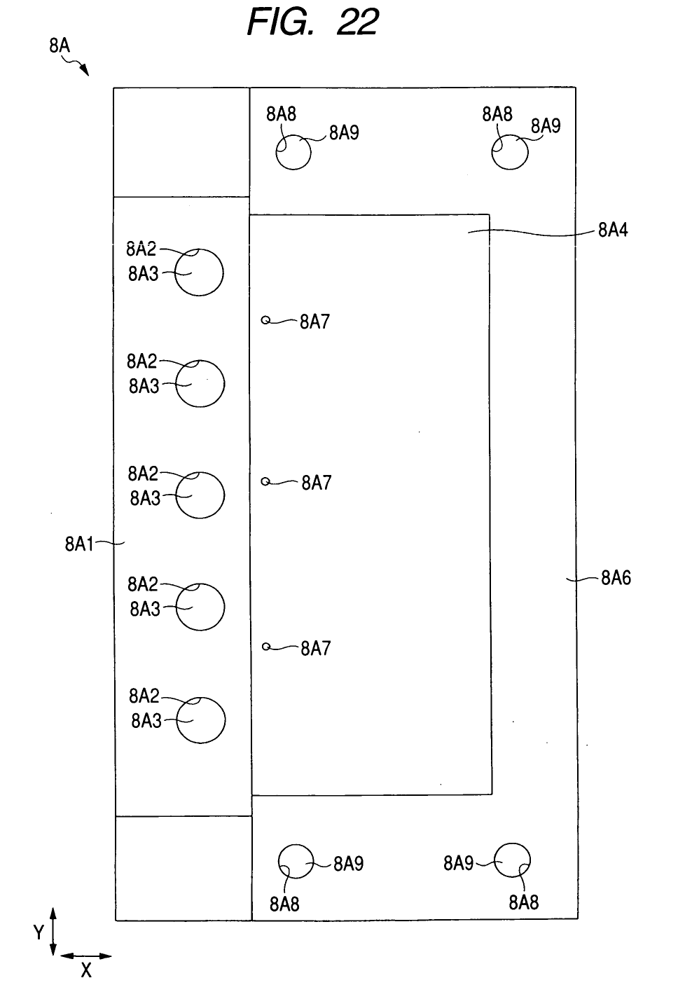

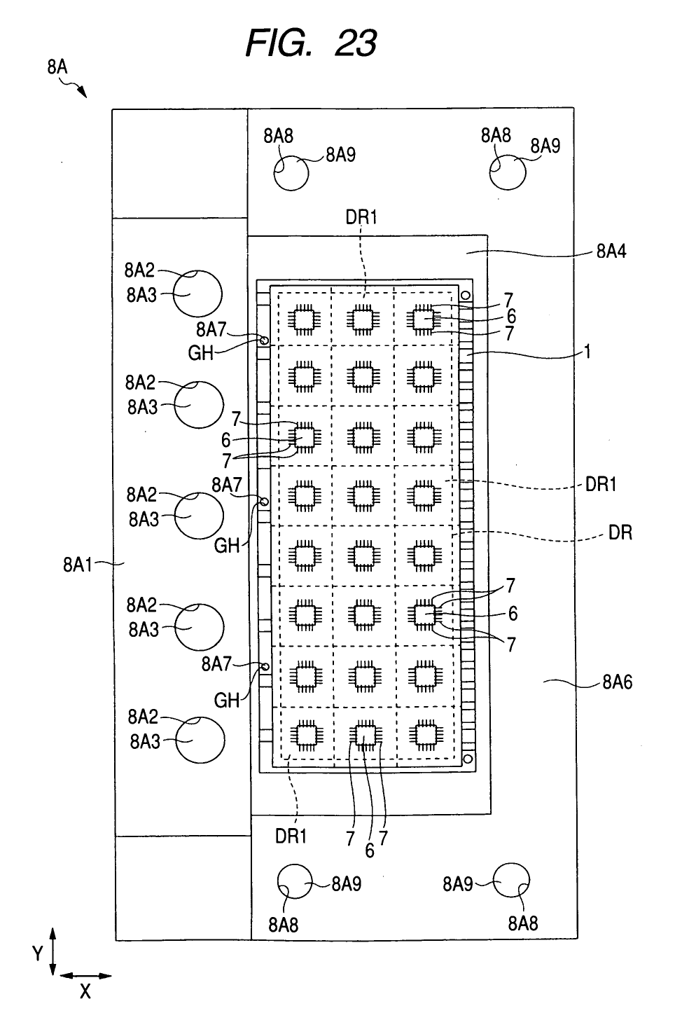

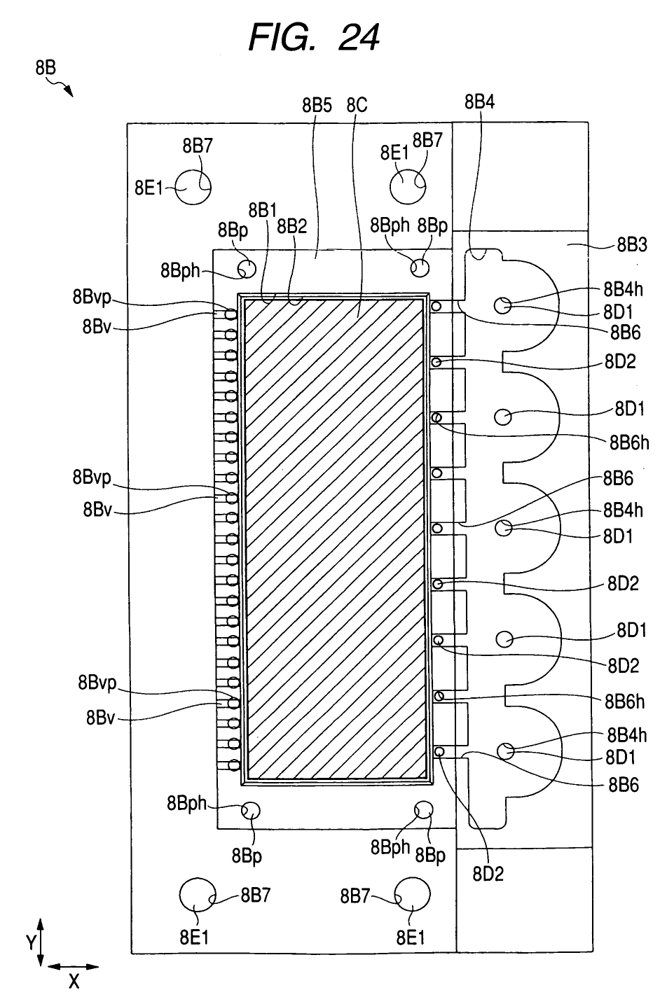

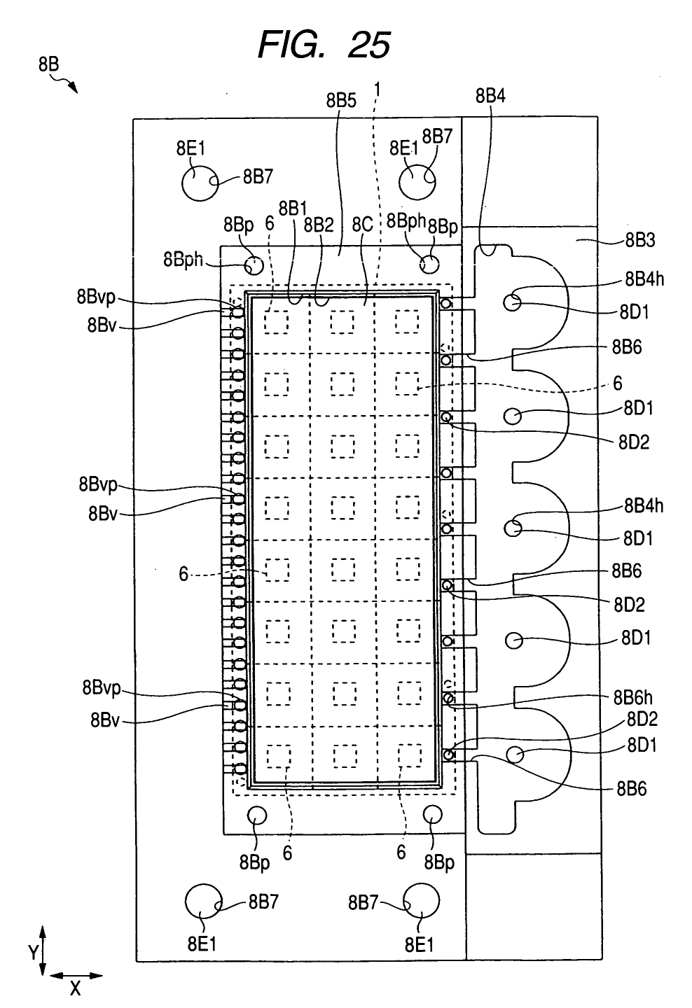

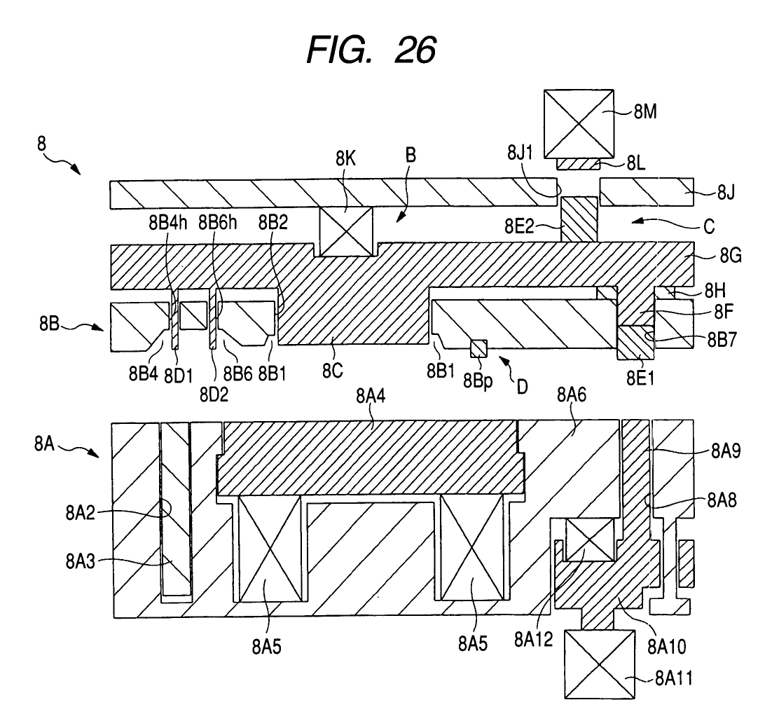

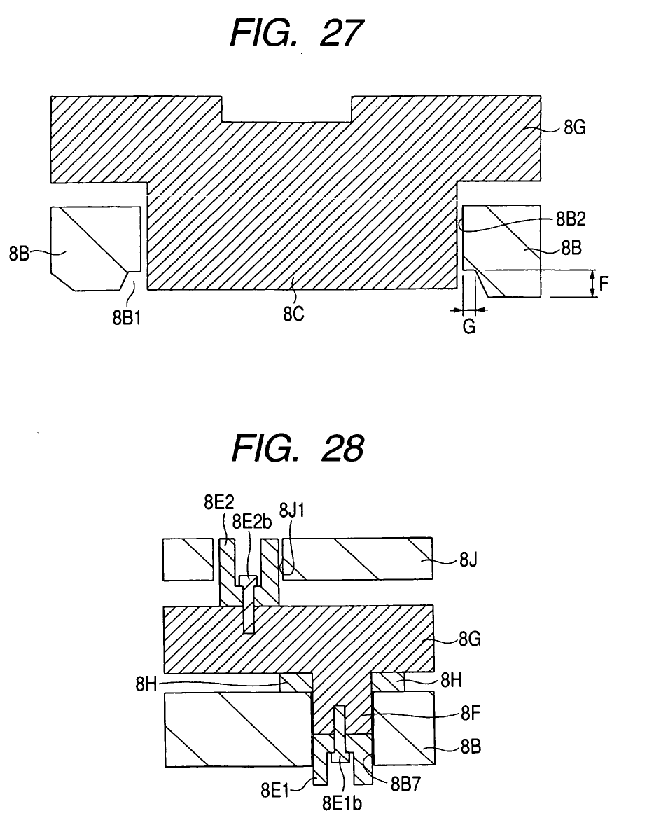

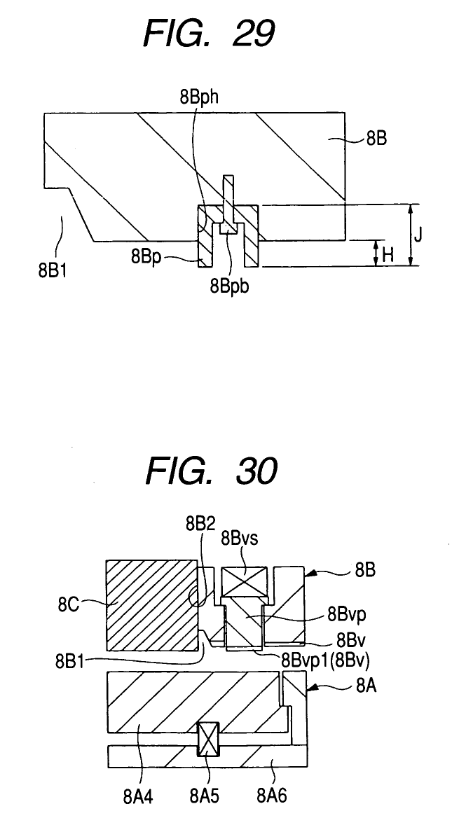

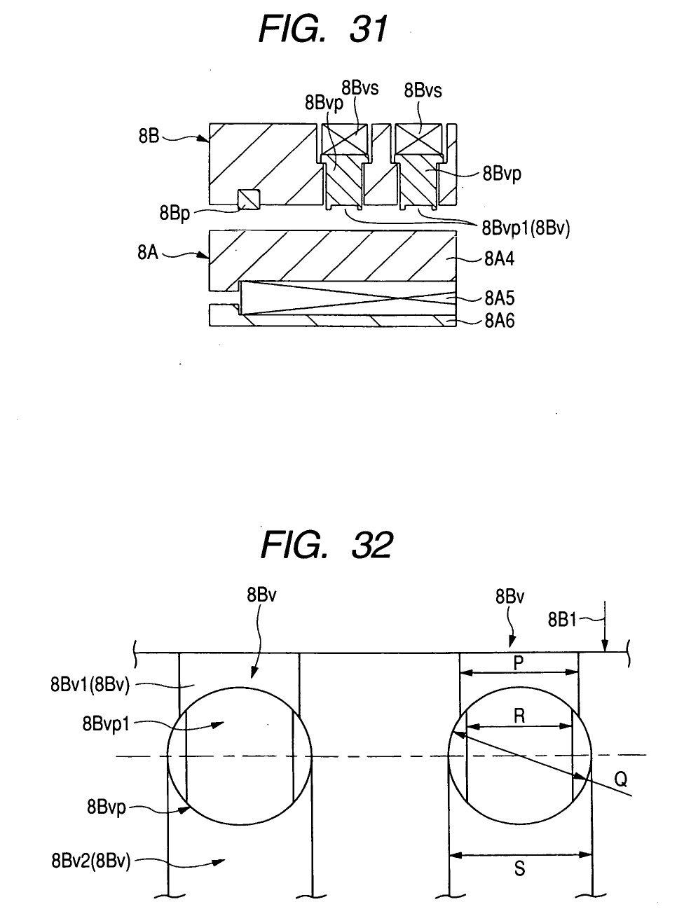

Next, description will be given to an example of the constitution of the mold 8 of the automatic molding equipment 20, referring to FIG. 21 to FIG. 32. FIG. 21 is a plan view illustrating the lower die 8A and the upper die 8B superposed together. FIG. 22 is a plan view of the molding surface of the lower die 8A. FIG. 23 is a plan view of the molding surface of the lower die, illustrating the way the board substrate 1 is placed on the molding surface of the lower die 8A in FIG. 22. FIG. 24 is a plan view of the molding surface of the upper die 8B. FIG. 25 is a plan view of the molding surface of the upper die, illustrating the positional relationship between the upper die 8B in FIG. 24 and the board substrate 1. FIG. 26 is a cross-sectional view taken along the line X2-X2 of FIG. 21. FIG. 27 to FIG. 29 are enlarged cross-sectional views of areas B to D in FIG. 26. FIG. 30 is a cross-sectional view taken along the line X3-X3 of FIG. 21. FIG. 31 is a cross-sectional view taken along the line X4-X4 of FIG. 21. FIG. 32 is an enlarged plan view of area E in FIG. 21. Though FIG. 24 is a plan view, the lower face of the movable cavity piece 8C is hatched to make the figure easy to view. The symbol X indicates a first direction, and the symbol Y indicates a second direction orthogonal to the first direction X.

The lower die 8A and the upper die 8B of the mold 8 are installed with their respective molding surfaces opposed to each other. This example is so constituted so that the lower die 8A is moved up and down. The size of the lower die 8A and the upper die 8B is so set that the dimension in the first direction X is, for example, 66 mm or so, and the dimension in the second direction Y is, for example, 152 mm or so.

A pot holder 8A1 is disposed on the left of the molding surface (surface opposed to the upper die 8B) of the lower die 8A in the first direction X (horizontal direction in FIG. 21, FIG. 22, and FIG. 23). On the pot holder 8A1, a plurality of pots 8A2 are disposed in line in the second direction Y (vertical direction in FIG. 21, FIG. 22, and FIG. 23). The pots 8A2 are supply ports for molding material, and each pot 8A2 is provided with a plunger 8A3. The plungers 8A3 are constituent units for pouring molding material in the pots 8A2 into the cavity CB and holding the material there under pressure. In this example, row plungers are illustrated.

A lower die cavity plate 8A4 is disposed on either side of the pot holder 8A1 on the molding surface of the lower die 8A. Elastic bodies 8A5, such as coil springs and leaf springs, are placed on the side of the rear face (face opposed to the molding surface) of the lower die cavity plate 8A4. Because of the elasticity of the elastic bodies 8A5, the lower die cavity plate 8A4 can be moved in the vertical direction in FIG. 26, FIG. 30, and FIG. 31. The elastic bodies 8A5 are provided with high-load elastic force so that the elastic bodies can withstand the resin injection pressure (approximately 4.9 MPa (50 kg/cm²) or above). The elastic force is at least equal to or above the resin injection pressure, more preferably, equal to or above 49 MPa (500 kg/cm²) or above, for example. The lower part of the lower die cavity plate 8A4 is so formed that its diameter is slightly larger. The stepped portion of the larger-diameter portion is bumped against the stepped portion of the base body 8A6 of the lower die 8A, and thereby the lower die cavity plate 8A4 is prevented from moving upward in FIG. 26, FIG. 30, and the FIG. 31.

A plurality of the guide pins 8A7 are provided on the molding surface of the lower die cavity plate 8A4 in proximity to either long side thereof along the long side. The guide pins 8A7 are inserted into the guide holes GH in the board substrate 1, as mentioned above, and thereby the board substrate 1 is positioned.

Four openings 8A8 are formed in the area outside the lower die cavity plate 8A4 on the molding surface of the lower die 8 so that the openings 8A8 are vertically and horizontally symmetrical. The upper face of an ejector rod 8A9 is exposed in each opening 8A8. The four ejector rods 8A9 are identical in the height of the exposed upper face. The four ejector rods 8A9 are formed integrally with one rod support portion 8A10. The ejector rods 8A9 are installed so that they can be simultaneously moved in the vertical direction in FIG. 26 by such a driving device 8A11 as a motor. The elastic bodies 8A12, such as coil springs and leaf springs, are installed between the upper face of the rod support portion 8A10 and the lower face of the base body 8A6. The ejector rods 8A9 are so constituted that they are moved downward in FIG. 26 by the elasticity of the elastic bodies 8A12. In this example, the mold 8 has a molding portion only either side of the pot holder 8A1. However, the present invention is not limited to this constitution, and, for example, a mold 8 having a molding portion on both sides of the pot holder 8A1 may be used. In this case, two board substrates 1 can be molded in one molding process.

A cull block 8B3 is disposed on the lower die opposed surface of the upper die 8B in the position opposite the pot holder 8A1 of the lower die 8A. In the cull block 8B3, a groove 8B4 for cull and runner is disposed so that the groove extends in the second direction Y in FIG. 21, FIG. 24, and FIG. 25. A plurality of openings 8B4h are formed in the groove 8B4 at predetermined intervals in the second direction Y in FIG. 21, FIG. 24, and FIG. 25, and parts of ejector pins 8D1 are exposed in the openings 8B4h. The ejector pins 8D1 are pins for separating resin left in the culls and the runners and the upper die 8B from each other, and installed so that the ejector pins 8D1 can be moved in the vertical direction in FIG. 26.

Further, an upper die cavity block 8B5 is installed on the upper die 8B in the position adjacent to the cull block 8B3 and opposite the lower die cavity plate 8A4 of the lower die 8A. The upper die cavity 8B1 is formed substantially in the center of the upper die cavity block 8B5. The plane dimensions of the upper die cavity 8B1 are, for example, as follows: the dimension in the first direction X is 60 mm or so, and the dimension in the second direction Y is 148 mm or so. The depth F of the upper die cavity 8B1 is set to the smallest thickness demanded of the present sealing bodes 9U, for example, 0.45 mm or so. The above-mentioned opening 8B2 is formed inside the upper die cavity 8B1. The plane dimensions of the opening 8B2 are set so that the following conditions are met: the opening 8B2 is sufficiently large to completely cover the product area DR; and the periphery of the opening 8B2 is positioned inside the corners of the bottom face of the recessed portion of the upper die cavity 8B1 by dimension G. More specifically, the dimension G is, for example, 1 mm or so, and the dimensions of the opening 8B2 are, for example, as follows: the dimension in the first direction X is 57 mm or so and the dimension in the second direction Y is 147 mm or so. The movable cavity piece 8C is fit into the opening 8B2 so that the movable cavity piece 8C can be moved in the vertical direction in FIG. 26. The dimensions of the lower face of the movable cavity piece 8C are substantially the same as those of the opening 8B2.

A plurality of gates 8B6 are formed between the upper die cavity 8B1 and the groove 8B4 so that the gates connect them. The gates 8B6 are injection ports for pouring molten resin for sealing, flowing from the groove 8B4, into the cavity CB. Each gate 8B6 has an opening 8B6h formed, and part of the ejector pin 8D2 is exposed in each opening 8B6h. The ejector pins 8D2 are pins for separating resin left in the gates 8B6 and the upper die 8B from each other, and are installed so that they are movable in the vertical direction in FIG. 26.

In the lower die opposed surface (area outside the upper die cavity 8B1) of the upper die 8B, an opening 8B7 is formed in positions opposite the four ejector rods 8A9 of the lower die 8A. The lower faces of blocks 8E1 are exposed in the openings 8B7. The blocks 8E1 are members provided with a function of adjusting the amount of vertical movement of the movable cavity piece 8C (that is, the thickness of the above-mentioned sealing body 9U). The blocks 8E1 are firmly fastened to rods 8F by bolts 8E1b so that the blocks 8E1 are detachable. The reason why the blocks 8E1 are detachable is for maintenance and replacement. The replacement of the blocks 8E1 includes: replacement for varying the amount of the vertical movement of the movable cavity piece 8C in accordance with change in the thickness of the sealing body 9U or the like; and replacement arising from deterioration in the blocks 8E1 or the like. If a member for varying the thickness of the sealing body 9U is provided in the cavity CB, the mold must be dismantled each time the thickness of the sealing body 9U is changed. This work is cumbersome and takes a lot of trouble and time. In the first embodiment, meanwhile, the blocks 8E1 which contribute to adjustment of the thickness of the sealing body 9U are provided in the non-cavity surface (lower die opposed surface) of the upper die 8B where the blocks are easy to remove. Therefore, the blocks 8E1 can be easily replaced without removing any other part of the mold 8, and thus change in the thickness of the sealing body 9U can be easily coped with in a short time. As a result, the delivery times of semiconductor devices can be shortened. If a member for varying the thickness of the sealing body 9U is provided in the cavity CB, the chance that sealing resin or the like may stick to the surface of the member is increased. If any foreign matter, such as sealing resin, sticks to the surface of a member for thickness change, a problem arises: the thickness of the sealing body 9U molded can deviate from a desired value. In the first embodiment, meanwhile, the blocks 8E1 are provided in the non-cavity surface (lower die opposed surface) of the upper die 8B, away from the cavity CB which is a source of foreign matter. Therefore, the chance that sealing resin or the like may stick to the surfaces of the blocks 8E1 can be reduced. Therefore, the occurrence of such troubles that the thickness of the sealing body 9U molded significantly deviates from a desired value can be reduced. As a result, the yield of semiconductor devices can be enhanced. The material of the blocks 8E1 is a metal, such as SKS and SKH, high in wear resistance. In the first embodiment, the blocks 8E1 are made of the same metal material as that of the upper die 8B. Thus, the thermal stability can be enhanced.

The movable cavity piece 8C, ejector pins 8D1 and 8D2, and rods 8F are connected with a support block 8G. Thus, the movable cavity piece 8C, ejector pins 8D1 and 8D2, and rods 8F are simultaneously moved in the same vertical direction in FIG. 26. The support block 8G is installed on the outside surface of the upper die 8B. Stoppers 8H are installed on the lower face (face opposed to the outside surface of the upper die 8B) of this support block 8G and on the circumference of the rods 8F. The stoppers 8H are members for stopping the downward movement of the support block 8G (that is, the movable cavity piece 8C, the ejector pins 8D1 and 8D2, and rods 8F) at a certain level. Further, blocks 8E2 are installed on the upper face of the support block 8G. The blocks 8E2 are members provided with the same functions as those of the above-mentioned blocks 8E1, and are firmly fastened to the support block BG by bolts 8E2b so that the blocks 8E2 are detachable. The reason why the blocks 8E2 are detachable is the same as why the blocks 8E1 are detachable. As mentioned above, the blocks 8E2 are provided on the non-cavity surface (outside surface) of the upper die 8B. As a result, change in the thickness of the sealing body 9U can be easily coped with in a short time for the same reason as described in connection with the blocks 8E1. Further, the occurrence of such troubles that the thickness of the sealing body 9U molded significantly deviates from a desired value can be reduced. The block 8E2 is installed, for example, in 12 places on the upper face of the support block 8G. The material of each block 8E2 is the same as that of the blocks 8E1. The dimensions of each block 8E2 are as follows: the diameter is, for example, 12 mm or so and the thickness is, for example, 10 mm or so. Each block 8E2 is small in area, and thus the accuracy of finishing can be enhanced. Also, torsion and the like are easy to control.

A fixed block 8J is installed above the support block 8G. Elastic bodies 8K, such as coil springs and leaf springs, are installed between the fixed block 8J and the support block 8G. For these elastic bodies 8K, a material which has energizing force exceeding the pressure produced in the support block 8G due to transfer thrust when resin injection into the cavity CB is used. For example, this embodiment uses a material which has energizing force three times the pressure produced during resin injection. An opening 8J1 is formed in the portions of the fixed block 8J opposite a plurality of the blocks 8E2. The plane dimensions of these openings 8J1 are slightly greater than the diameter of the blocks 8E2. Stoppers 8L are installed above the openings 8J1. The stoppers 8L are members for preventing the support block 8G from being pushed up by the resin injection pressure during resin injection into the cavity CB. These stoppers 8L are in such a state that they can be moved in the vertical direction in FIG. 26 by such a driving device 8M as a motor. During resin injection, the stoppers 8L are caused to work with the driving device 8M at a stop. To prevent the stoppers 8L from being moved by pressure produced due to resin injection the driving device 8M must withstand pressure equal to or higher than the pressure produced due to resin injection when at a stop. For example, this embodiment uses a driving device 8M which can withstand pressure three times the above-mentioned pressure when at a stop.

A plurality of air vents 8Bv are extended from the other long side of the upper die cavity 8B1 in such a direction that the air vents 8Bv get away from the upper die cavity 8B1. The air vents 8Bv are grooves for discharging the air in the resin filled areas to the outside when resin is injected into the upper die cavity 8B1. By disposing a plurality of the air vents 8Bv as mentioned above, the air in the resin filled areas can be favorably discharged to the outside during resin injection. Therefore, the resin for sealing can be favorably filled in the cavity CB. A movable pin 8Bvp is disposed at some midpoint in each air vent 8Bv. Before the mold 8 is closed, the lower end portions of the movable pins 8Bvp are protruded into the air vents 8Bv. A groove 8Bvp1 is formed in the lower end faces of the movable pins 8Bvp. The grooves 8Bvp1 form part of the air vents 8Bv. Elastic bodies 8Bvs, such as coil springs and leaf springs, are installed on the upper end face side (faces on the opposite side to the lower end faces of the movable pins 8Bvp) of the movable pins 8Bvp. Therefore, when the mold 8 is closed and the board substrate 1 is clamped and held between the lower die 8A and the upper die 8B, the movable pins 8Bvp are pressed by the principal surface of the board substrate 1 and are moved toward the upper die 8B. Therefore, the elastic bodies 8Bvs above the movable pins 8Bvp are compressed, and further the lower end faces of the movable pins 8Bvp are caused to hold down the principal surface of the board substrate 1 by repulsive force from the elastic bodies 8Bvs. Thus, even if there is variation in the thickness of the board substrate 1 or unevenness on the principal surface (element placement face) of the board substrate 1 due to wiring (conductor patterns) or the like, no problem arises: when the board substrate 1 is clamped in the mold 8, the lower end faces of the movable pins 8Bvp protruded into the air vents 8Bv automatically adapt to the principal surface of the board substrate 1 in respective positions on the principal surface. Thus, the lower end faces of the movable pins 8Bvp come into tight contact with the board substrate 1. At this time, even if the stop positions of the movable pins 8Bvp in the vertical direction differ from pin to pin due to variation in the thickness of the board substrate 1 or the state of the principal surface, no problem arises: as long as the depth of the grooves 8Bvp1 in the lower end faces of the movable pins 8Bvp is constant, the depth of each air vent 8Bv can be automatically made constant. Therefore, the air in the resin filled areas can be favorably discharged to the outside during resin injection, and the resin for sealing can be favorably filled in the cavity CB. In the molding process, the resin injection pressure is applied directly to the air vents 8Bv. Since their area is small, however, the elastic force of the elastic bodies 8Bvs on the movable pins 8Bvp only has to be sufficient to lightly press the board substrate 1. More specific description will be given. The elastic force of the elastic bodies 8Bvs is far smaller than the clamp pressure (e.g. 49 MPa (500 kg/cm²)) of the mold 8 on the board substrate 1. At the same time, the elastic force is at such a level that the board substrate 1 will not be deformed or damaged. At the same time, it is preferable that the elastic force should be higher than the pressure applied to the air vents 8Bv due to resin injection and be at the level sufficient to prevent the leakage of resin. More specifically, a load of, for example, 6.86 MPa (70 kg/cm²) or so is provided. Further, the elastic force of the elastic bodies 8Bvs is so set that the amount of movement of the movable pins 8Bvp will be, for example, 100 to 200 μm or so.

The air vent 8Bv is divided into four parts: movable pin front part 8Bv1, movable pin part (or air vent major part, equivalent to the groove 8Bvp1), movable pin rear part 8Bv2, and open part in line with the flow path from the upper die cavity 8B1. The movable pin front part 8Bv1 will be described. The tolerance on the thickness of the board substrate 1 is set to, for example, ±30 μm or so. Even in case that the board substrate 1 is thickest, the depth is set to 60 to 70 μm or so. Thus, the effective depth of 30 to 40 μm or so can be ensured with respect to the air vents 8Bv. The depth of cut of the movable pins 8Bvp is, for example, 40 to 50 μm or so. With respect to the movable pin rear part 8Bv2, the depth setting of 50 to 60 μm or so is sufficient. This is because the movable pin rear part 8Bv2 immediately connects to the open part which has a depth of 150 μm or so. As mentioned above, the effective depth of the major parts of the air vents 8Bv can be made constant regardless of the thickness of the board substrate 1 and the like (including lead frames) Thereby, the leakage of resin and the like can be effectively prevented without excessively increasing the clamp force of the mold 8. (In case of the above example, they can be prevented without applying up to 25000 kg force per board substrate 1 to excessively deform the board substrate 1.) If the thickness of the board substrate 1 is small in the negative direction of tolerance, the leakage of resin is prone to occur. In the mold 8 in the first embodiment, the movable pins 8Bvp are lightly held down by the elastic force from the elastic bodies 8Bvs, and the injection pressure of the resin material does not have direct influence. Therefore, the leakage of resin from the air vents 8Bv can be blocked. In the air vents 8Bv, the depth of the movable pin front part 8Bv1 and the depth of the movable pin rear part 8Bv2 are different from each other. The depth of the movable pin front part 8Bv1 is greater than the depth of the movable pin rear part 8Bv2. By making the movable pin front part 8Bv1 deeper, as mentioned above, the following advantage is brought: even if the thickness of the board substrate 1 fluctuates, the air vents 8Bv are not blocked by the fluctuation, and areas for the air vents 8Bv can be ensured without fail. The vent width P of the movable pin front part 8Bv1 of the air vents 8Bv is smaller than the diameter of the movable pins 8Bvp. More specifically, the following dimensions are preferable: the diameter Q of the movable pins 8Bvp is, for example, 5 mm or so; the vent width P of the movable pin front part 8Bv1 is, for example, 4 mm or so; the vent width S of the movable pin rear part 8Bv2 is, for example, 5 mm or so; and the width R of the grooves 8Bvp1 in the lower end faces of the movable pins 8Bvp is, for example, 2 to 3 mm or so. By setting these diameters as mentioned above, the leakage of resin for sealing can be blocked by the movable pins 8Bvp even if the board substrate 1 is formed so that the board substrate is thin in the negative direction of the tolerance on its thickness. Therefore, the leakage of resin for sealing can be prevented without fail.

A block pin 8Bp is detachably installed on the molding surface of the upper die 8B in proximity to the four corners of the peripheral portion of the upper die cavity 8B1, outside the outline of the board substrate 1. In terms of cross sections, the block pins 8Bp are slightly protruded from the molding surface of the peripheral portion of the upper die cavity 8B1 in the direction orthogonal to the molding surface. Thus, in the molding process, the molding surface of the peripheral portion of the upper die cavity 8B1 hits the peripheral portion of the principal surface (element placement face) of the board substrate 1. Then, it deforms the board substrate 1 sufficiently to prevent the leakage of resin, and thereafter presses down the lower die cavity plate 8A4 of the lower die 8A. As a result, during the molding process, excessive pressure is suppressed or prevented from being applied to the board substrate 1 when the board substrate 1 is clamped between the upper die 8B and the lower die 8A. Therefore, deformation, cracking, and the like in the board substrate 1 due to crushing can be prevented. At this time, the amount of deformation in the principal surface of the board substrate 1 due to the molding surface (lower die opposed surface) of the peripheral portion of the upper die cavity 8B1 is, for example, 30 μm to 40 μm or so.

The block pins 8Bp are inserted in guide holes 8Bph formed in the upper die 8B and firmly fastened by bolts 8Bpb so that the blockpins 8Bp are detachable The reason why the block pins 8Bp are detachable is for maintenance and replacement. The replacement of the block pins 8Bp includes: replacement for varying the protrusion length H of the block pins 8Bp in accordance with change in the thickness of the board substrate 1 or the like. (The protrusion length H is the length of the portions protruded from the lower die opposed surface of the upper die 8B); and replacement arising from deterioration in the block pins 8Bp or the like. The protrusion length H of the block pins 8Bp from the molding surface of the upper die 8B which is brought into contact with the board substrate 1 is set from the viewpoint of ensuring an appropriate amount of deformation in the board substrate 1. For example, if the thickness of the board substrate 1 is 0.3 mm, the protrusion length H is set to, for example, 0.27 mm. Thus, an amount of deformation of 0.03 mm or so can be ensured in the board substrate 1. The overall length J of the block pins 8 is, for example, 15 mm or so. The material of the block pins 8Bp is a metal, such as SKS and SKH, high in wear resistance. In the first embodiment, the block pins 8Bp are made of the same metal material as that of the upper die 8B. Thus, the thermal stability can be enhanced.

The shape of the flat faces (pressing faces) of the block pins 8Bp is, for example, circular. By forming the flat faces of the block pins 8Bp in circular shape, machining of the guide holes 8Bph and the block pins 8Bp themselves is facilitated, and further the cost can be reduced. Further, the strength of the block pins 8Bp can be enhanced, and the block pins 8Bp can be made crushproof. The diameter of the lower faces of the block pins 8Bp is, for example, 8 to 10 mm or so. The block pins 8Bp are disposed symmetrically in the vertical direction and in the horizontal direction. Thus, the pressing force of each block pin 8Bp on the lower die cavity plate 8A4 can be made uniform. For the block pins 8Bp having a circular flat face (pressing face) , it is preferable that four block pins or so should be disposed for the upper die cavity 8B1. This is because of the following reasons: if an excessively large number of block pins 8Bp are disposed, a large number of guide holes 8Bph are formed in the upper die 8B. This can impair the mechanical strength of the upper die 8B and cause distortion or the like in the upper die 8B. As a result, the accuracy for mold can be degraded. In addition, the upper die 8B a involves other components, such as a heater, and too many block pins can interfere with such other components. Furthermore, too many block pins 8Bp can impair the stability of the points of contact of the block pins 8Bp. There are also cases where a heater is not disposed on the upper die 8B. As a modification to the block pins 8Bp, those having a flat face (pressing face) whose aspect ration is not 1:1, such as those having a rectangular flat face, may be used. In this case, a block pin 8Bp only has to be disposed in two places or so in the upper die cavity 8B1. Therefore, the number of parts can be reduced, and the cost can be reduced as well.

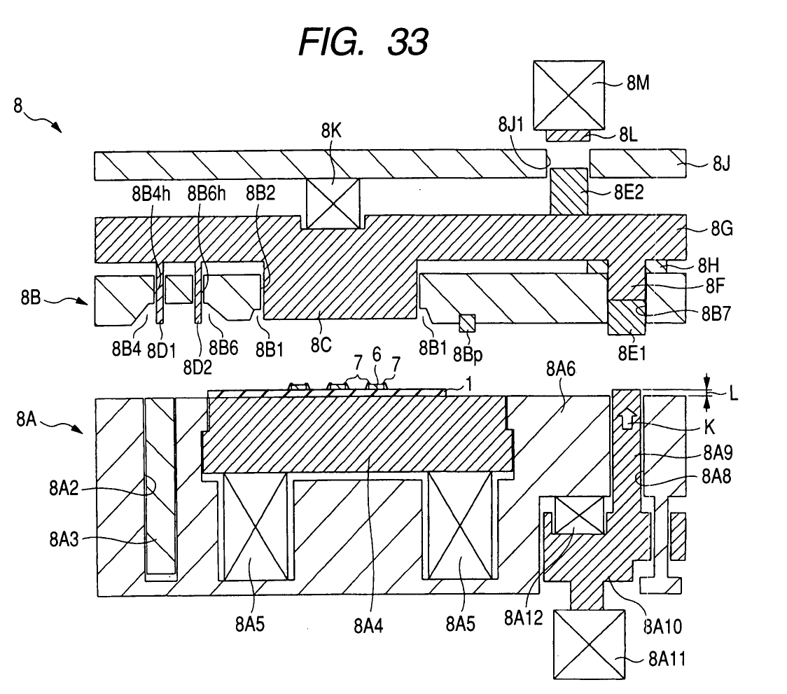

Next, description will be given to an example of the molding process using the above-mentioned mold 8, referring to FIG. 33 to FIG. 41.

First, a board substrate 1 which underwent the chip bonding step and the wire bonding step is placed on the lower die cavity plate 8A4 of the mold 8 in alignment, as illustrated in FIG. 33. Thereafter, the ejector rods 8A9 are moved up in the direction indicated by arrow K by driving force from the driving device 8A11. Thereby, the tips of the ejector rods 8A9 are protruded from the molding surface of the lower die 8A by length L. The reason is as follow: if the lower die 8A and the upper die 8B are closed together without protruding the tips of the ejector rods 8A9, the undersurface of the movable cavity piece 8C is brought into contact with chips 6 or bonding wires 7. Length L is, for example, 1 to 2.5 mm or so. At this time, the lower die cavity plate 8A4 is pushed by the elastic bodies 8A5, and the upper face of the lower die cavity plate 8A4 becomes flush with the upper face of the base body 8A6.

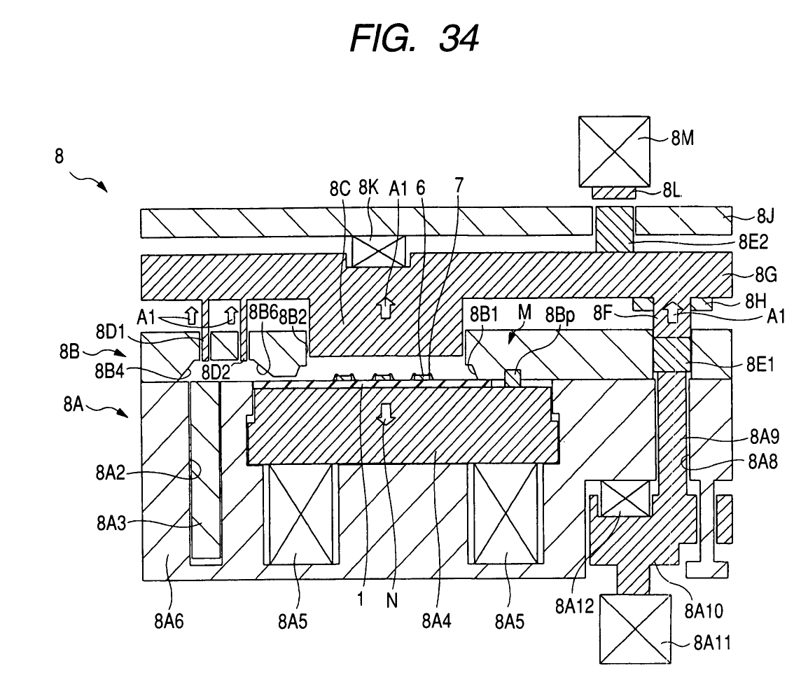

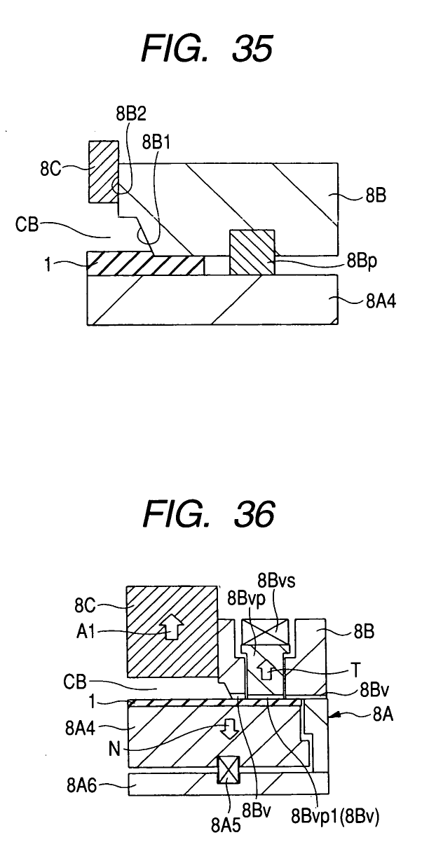

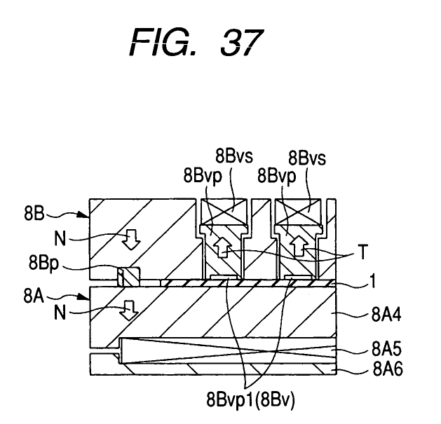

As illustrated in FIG. 34, subsequently, the lower die 8A and the upper die 8B are closed together, and the board substrate 1 is clamped and held between the lower die 8A and the upper die 8B. FIG. 35 is an enlarged cross-sectional view of area M in FIG. 34. FIG. 36 is a cross-sectional view taken along the line X3-X3 of FIG. 21 in the same step as illustrated in FIG. 34. FIG. 37 is a cross-sectional view taken along the line X4-X4 of FIG. 21 in the same step as illustrated in FIG. 34. When the lower die 8A and the upper die 8B are closed together, as mentioned above, the ejector rods 8A9 on the lower die 8A side are brought into contact with the blocks 8E1 on the upper die 8B side. As a result, the support block 8G is pushed up in the direction indicated by arrow A1 in FIG. 34. Thus, the movable cavity piece 8C and the ejector pins 8D1 and 8D2 are also moved in the direction indicated by arrow A1 in FIG. 34. By adjusting the distance of this vertical movement of the movable cavity piece 8C, the thickness of the above-mentioned sealing body 9U can be set as desired. Therefore, change in the thickness of the sealing body 9U can be easily coped with in a short time, and the delivery times of semiconductor devices can be shortened. Further, the range of error in the thickness of the sealing body 9U can be reduced to ±5 μm or below, and thus the accuracy of formation of the thickness of the sealing body can be enhanced. Further, change in the thickness of the sealing body 9U can be coped with by a single mold 8. Therefore, it becomes unnecessary to purchase a new mold when the thickness of the sealing body 9U is changed, and jig and tooling costs can be reduced. In addition, existing molding facilities can be used, and initial investments can be reduced. Because of these and the like, the development costs and manufacturing costs of semiconductor devices can be reduced. Here again, a case where the lower face of the movable cavity piece 8C is higher than the bottom face of the recess in the upper die cavity 8B1 is taken as an example.

The first embodiment is constituted so that the following takes place: when the lower die 8A and the upper die 8B are closed together, the peripheral portion of the cavity 8B1 in the upper die 8B hits the peripheral portion of the principal surface (element placement face) of the board substrate 1. Then, it deforms the board substrate 1 sufficiently to prevent the leakage of resin, and thereafter the block pins 8Bp of the upper die 8B press down the lower die cavity plate 8A4 in the direction indicated by arrow N. As a result, when the board substrate 1 is clamped between the upper die 8B and the lower die 8A, excessive pressure is suppressed or prevented from being applied to the board substrate 1. Therefore, deformation, cracking, and the like in the board substrate 1 due to crushing can be suppressed or prevented. Thus, the yield of semiconductor devices can be enhanced. At this time, the portion of the board substrate 1 on which clamp force is exerted is an annular area, 1 mm or so in width, corresponding to the peripheral portion of the upper die cavity 8B1. It is assumed that the board substrate 1 is a rectangle in 151 mm×66 mm. In this case, the dimensions of the portion of the board substrate 1 on which clamp force is 148 mm×60 mm×0.8 mm in width, and its area, excluding the air vents 8Bv and the gates 8B6, is approximately 1000 mm². In the first embodiment, if a force of 490 MPa (500 kg/cm²) or so is applied to the board substrate 1 when clamped, a force of 42.1 MPa (430 kg/cm²) or so can be absorbed by the block pin 8Bp portions. Therefore, the force applied to the peripheral portion of the board substrate 1, held down by the upper die 8B can be reduced to 68.6 MPa (770 kg/cm²) or so. That is, the pressure in the area where the molding surface of the upper die 8B hits the board substrate 1 is lower than the pressure at the block pin 8Bp portions. If the pressure applied to the board substrate 1 is high, problems, such as cracking in the board substrate 1, can result. In this case, therefore, the elastic force of the elastic bodies 8A5 under the lower die cavity plate 8A4 must be lowered. However, if the elastic force of the elastic bodies 8A5 is lowered, a problem of the leakage of resin arises during resin injection. In the first embodiment, the pressure exerted on the board substrate 1 can be reduced without lowering the elastic force of the elastic bodies 8A5 under the lower die cavity plate 8A4. Therefore, the problem of the leakage of resin onto the principal surface of the board substrate 1 does not arise during the molding process. If the product type of the board substrate 1 is changed and its thickness significantly differs, the block pins 8BP can be correspondingly changed to obtain an appropriate protrusion length H.

In the first embodiment, as mentioned above, the following takes place when the board substrate 1 is clamped between the upper die 8B and the lower die 8A in the molding process: the movable pins 8Bvp protruded on the air vent 8Bv side are pushed from the board substrate 1 side, and are moved in the direction indicated by arrow T in FIG. 36 and FIG. 37. Thus, the air vents 8Bv composed of the movable pin front part 8Bv1, groove 8Bvp1, and movable pin rear part 8Bv2 can be formed, and flow paths for discharging the air in the resin filled area (cavity CB) to the outside can be ensured. Therefore, the molten resin for sealing can be favorably filled in the cavity CB. At the same time, the movable pins 8Bvp appropriately hold down the principal surface of the board substrate 1 by the elastic force from the elastic bodies 8Bvs above the movable pins 8Bvp. Thus, the problem of the leakage of resin onto the principal surface of the board substrate 1 does not arise in the areas of the air vents 8Bv.

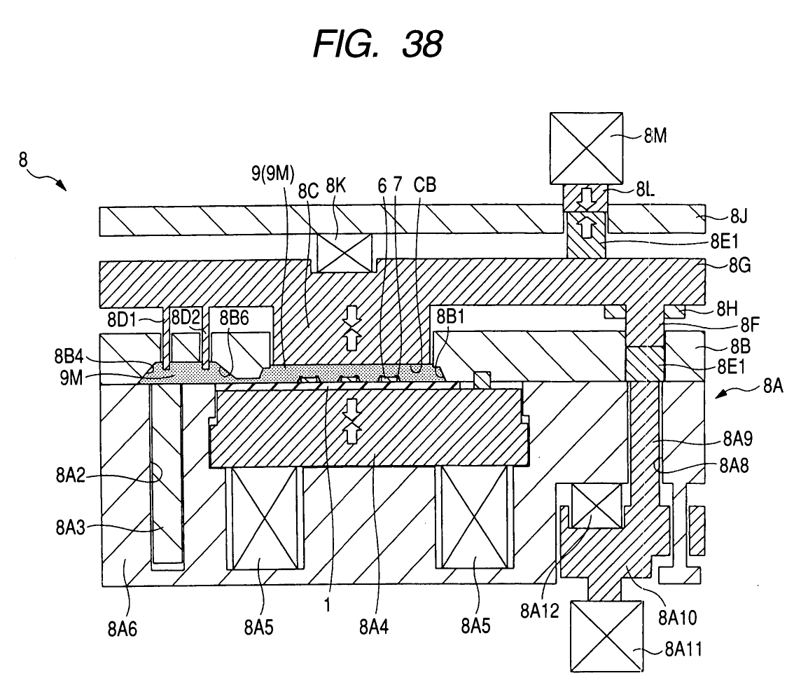

As illustrated in FIG. 38, subsequently, the ejector rods 8A9 and the stoppers 8L are moved down by 1 mm or so. By moving down the stoppers 8L, the support block 8G is prevented from being lifted by the resin injection pressure. Thus, the cavity CB encircled with the upper die cavity 8B1, movable cavity piece 8C, and board substrate 1 is formed. At this time, the tips of the ejector pins 8D1 and 8D2 are protruded into the groove 8B4 and the gates 8B6. Thereafter, the molten resin 9M (hatched) in the pots 8A2 is pushed out to the groove 8B4 by the plungers 8A3, and is poured into the cavity CB through the gates 8B6. As mentioned above, the peripheral portion of the principal surface of the board substrate 1 is held down by the upper die 8B under appropriate pressure. Therefore, the molten resin 9M for sealing can be filled into the cavity CB without excessive crush, cracking, the leakage of resin, or the like. Thus, the blanket sealing body 9 is molded. In the first embodiment, the rate of occurrence of poor appearance of the blanket sealing body 9 due to the mold 8 can be reduced, and thus the appearance inspection can be simplified. The arrows in FIG. 38 indicate force in equilibrium.

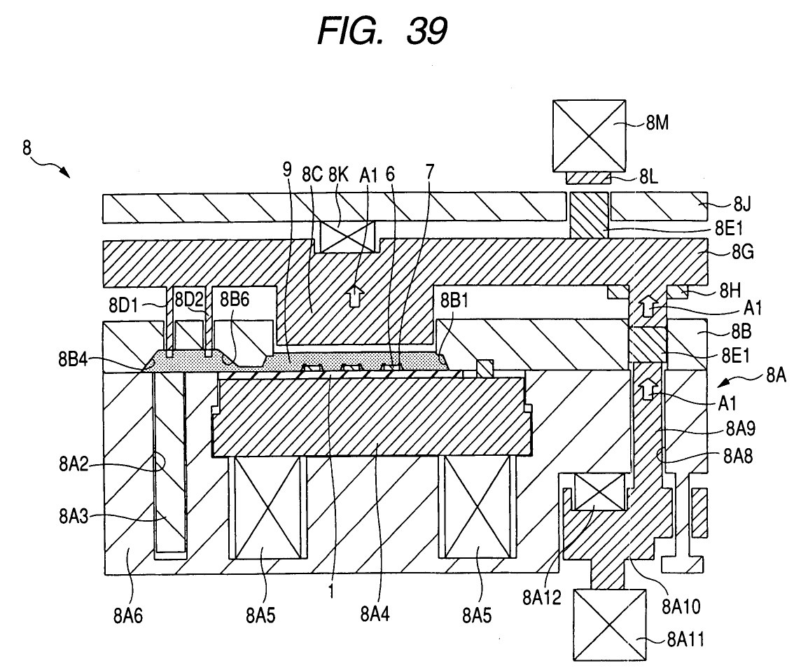

As illustrated in FIG. 39, following the completion of the molding, the stoppers 8L and the ejector rods 8A9 are moved up by 1 mm or so in the direction indicated by arrow A1 before the lower die 8A and the upper die 8B are opened. Thereby, the support block 8G is moved up in the direction indicated by arrow A1. Consequently, the movable cavity piece 8C and the ejector pins 8D1 and 8D2 connected with the support block 8G are also moved up in the direction indicated by arrow A1. Thus, the movable cavity piece 8C is separated from the blanket sealing body 9, and at the same time, the ejector pins 8D1 and 8D2 are also separated from the resin in the groove 8B4 and the gates 8B6. For this reason, the movable cavity piece 8C can be easily released from the blanket sealing body 9 without damage to the blanket sealing body 9. Therefore, the releasability between the upper die 8B and the blanket sealing body 9 can be enhanced. Further, force for mold release is not applied directly to the chips 6. Therefore, chip crack failure can be prevented, and the yield and reliability of semiconductor devices can be enhanced. If the lower die 8A and the upper die 8B are opened without moving up the ejector rods 8A9, the blanket sealing body 9 is sandwiched between the movable cavity piece 8C and the lower die 8A, and can become cracked.

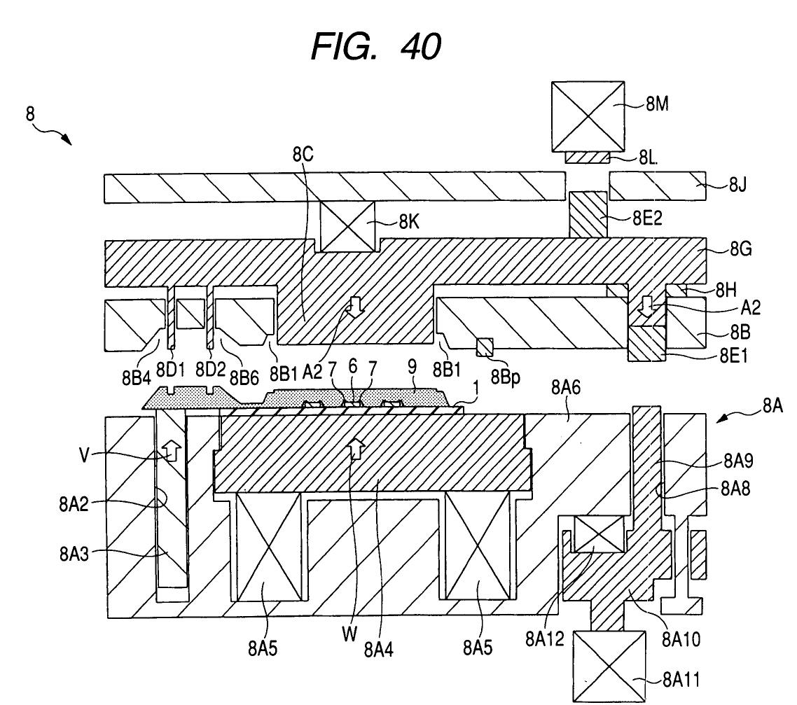

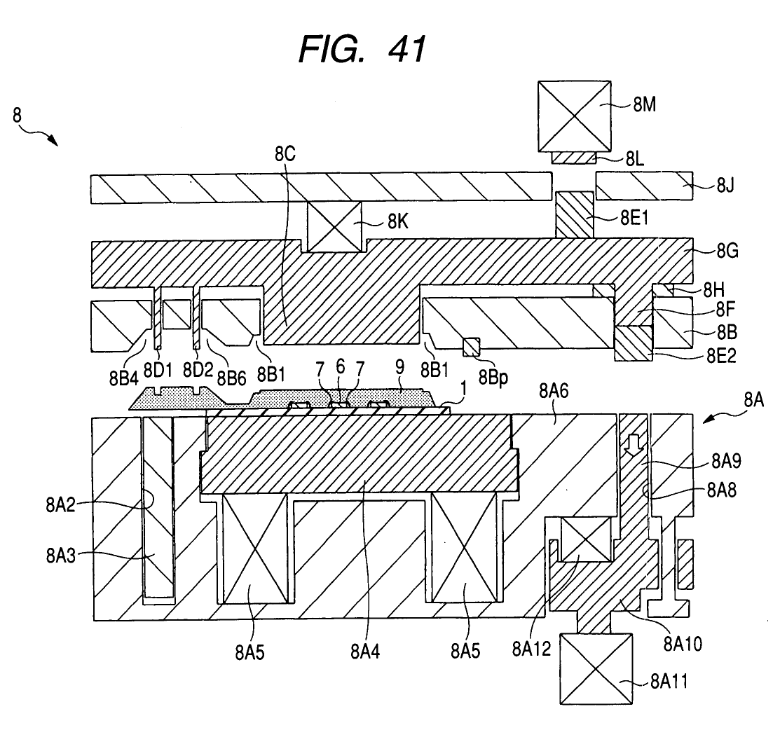

As illustrated in FIG. 40, thereafter, the ejector rods 8A9 are kept up, and the lower die 8A and the upper die 8B are opened. At this time, the blanket sealing body 9 and the resin left in the groove 8B4 and the gates 8B6 are pushed out by the movable cavity piece 8C and the ejector pins 8D1 and 8D2. Thereby, the blanket sealing body 9 and the resin are separated from the upper die 8B. At this time, the plungers 8A3 are also moved up in the direction indicated by arrow V at the same speed as the mold opening speed. When the lower die 8A and the upper die 8B are opened, the support block 8G is moved down in the direction indicated by arrow A2 by the elastic force of the elastic bodies 8K. When the stoppers 8H hit the upper face of the upper die 8B, however, the descent is stopped. Since the pressing force from the upper die 8B side is removed, meanwhile, the lower die cavity plate 8A4 is moved up in the direction indicated by arrow W by the elastic force from the elastic bodies 8A5. The lower die cavity plate 8A4 then goes back to its original position. As illustrated in FIG. 41, thereafter, the ejector rods 8A9 are moved down in the direction indicated by arrow by 1 mm or so, and then the board substrate 1 is carried out.

According to the first embodiment, the following effects can be obtained:
(1) The thickness of the above-mentioned sealing body 9U can be set as desired by adjusting the distance of vertical movement of the movable cavity piece 8C. Therefore, change in the thickness of the sealing body 9U can be easily coped with in a short time, and the delivery times of semiconductor devices can be shortened.
(2) The accuracy of formation of the thickness of the sealing body 9U can be enhanced.
(3) Change in the thickness of the sealing body 9U can be coped with by a single mold 8. Therefore, it becomes unnecessary to purchase a new mold when the thickness of the sealing body 9U is changed, and jig and tooling costs can be reduced. In addition, existing molding facilities can be used, and initial investments can be reduced. Because of these and the like, the development costs and manufacturing costs of semiconductor devices can be reduced.
(4) The blanket sealing body 9 can be released directly from the cavity face of the mold 8. One of the methods for releasing a molded blanket sealing body 9 from a mold 8 is laminate method. This method is such that a blanket sealing body 9 is released from a mold using a laminate film placed between the cavity face of the mold 8 and the blanket sealing body 9. In this method, there is no problem associated with mold release. However, since the film is changed each time the molding process is carried out, the product direct material cost is increased. Further, the mold 8 must be equipped with a transport mechanism for laminate films, and the laminate method cannot be carried out with existing molding equipment. Therefore, the molding equipment must be retrofitted or new molding equipment must be purchased, and initial investments are required. Further, the tact time in molding is lengthened. In the first embodiment, meanwhile, the blanket sealing body 9 can be released from the mold 8 without use of laminate films. Therefore, the product direct material cost can be reduced. Further, a transport mechanism for laminate films is unnecessary, and existing molding equipment can be used. Therefore, it is not required to retrofit molding equipment or purchase new molding equipment, and the initial investments can be reduced. As a result, the development costs and the manufacturing costs of semiconductor devices can be reduced. A step in which a laminate film is disposed prior to the molding process is unnecessary, and the tact time in molding can be shortened. Therefore, the time periods required for developing and manufacturing semiconductor devices can shortened.
(5) The necessity for pins for releasing a blanket sealing body 9 from the cavity face of a mold 8 can be obviated. One of the methods for releasing a molded blanket sealing body 9 from a mold 8 is pin method. This method is such that the peripheral area on the upper face of the blanket sealing body 9 (peripheral area of the product area) is directly pushed by pins, and thereby the blanket sealing body 9 is released from the mold. In this method, some problems are caused: if a pin for mold release hits the product area, a trace of the pin is left or damage or the like is caused in the product area, and poor appearance results; chips are caused to crack by the pressing force of a pin for mold release; or a pin for mold release is brought into contact with bonding wires. To prevent these problems, pins are made to hit the area around the product area. To increase the number of products acquired as much as possible, the product area tends to be expanded. The portion on the upper face of the blanket sealing body 9 remaining outside the product area has been significantly narrowed to, for example, 2 mm or below. For this reason, the diameter allowed to pins for mold release is as minute as 1.6 mm or below, for example. This degrades the strength of pins and increases the frequency of pin breakage. Further, pins for mold release are thin, and the area of the pressing portions of the pins is no more than 1/50 or 1/60 of the area of contact between the blanket sealing body 9 and the mold. For this reason, sufficient pressing force cannot be applied to the blanket sealing body 9. Since the edge of the peripheral portion of the product area is pushed by the thin pins, the pressing force is applied to the blanket sealing body 9 in an ill-balanced manner. Thus, the blanket sealing body 9 cannot be favorably released from the mold. This can excessively distort the blanket sealing body 9 and damage to semiconductor devices can result. To prevent these problems, the releasability, that is, ease of releasing the blanket sealing body 9 from the mold, must be kept high. As a result, some problems arise: a cleaning step for removing the blanket sealing body 9 stuck to the mold or like purposes must be added, and the number of times by which the molding process is continuously carried out is reduced. That is, the continuous moldability is degraded, and the time required for manufacturing semiconductor devices is increases. As the area of the blanket sealing body 9 is increased, these problems become more pronounced because mold release becomes especially difficult. To prevent these problems, the releasability, that is, ease of releasing the blanket sealing body 9 from the mold must be kept high. If circuit boards 1A are warped due to thermal shrinkage in the cut sealing bodies 9U, the semiconductor devices cannot be favorably mounted on mounting boards. Therefore, recently, a material which does not shrink is used as the resin material for the blanket sealing body 9 in molding. More specifically, the amount of filler in sealing resin is increased to reduce shrinkage. However, this poses a problem. Mold release is carried out as follows: the molded blanket sealing body 9 shrinks, and thus a gap is produced between the blanket sealing body 9 and the mold. In this state, the blanket sealing body 9 is pushed out by pins. For this reason, use of a resin material that is less shrinkable poses a problem. The molded blanket sealing body 9 does not shrink, and a gap is not produced between the blanket sealing body 9 and the upper die 8B. This makes it more difficult to release the blanket sealing body 9 from the mold. In the first embodiment, meanwhile, failure in releasing the blanket sealing body 9 from the mold can be eliminated. Therefore, the continuous moldability can be enhanced, and the efficiency of utilization of automatic molding equipment can be enhanced. As a result, the time required for manufacturing semiconductor devices can be shortened. Further, since the movable cavity piece 8C is broken away from the blanket sealing body 9 before mold release is carried out, the force of ejectors is not applied directly to the blanket sealing body 9. For this reason, the blanket sealing body 9 is not damaged, the chips 6 do not crack, or the bonding wires 7 are not exposed during mold release. Therefore, the yield and reliability of semiconductor devices can be enhanced. For this reason, the manufacturing costs of semiconductor devices can be reduced.

### Second Embodiment

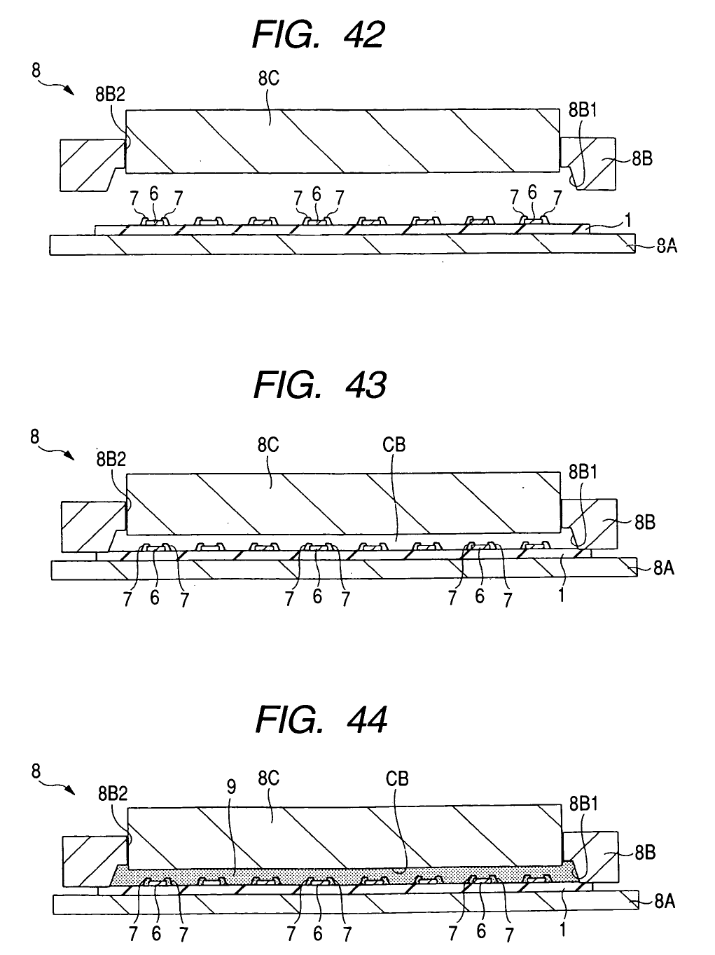

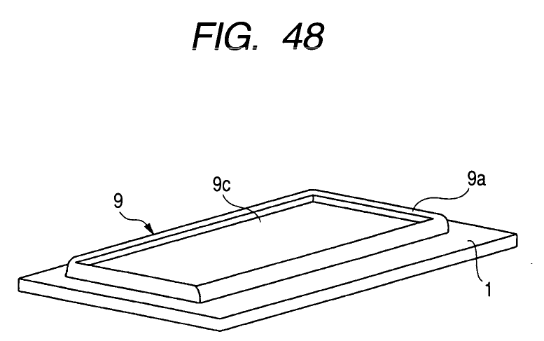

The second embodiment is a case where a thinner sealing body 9U is demanded. An example of this case will be described referring to FIG. 42 to FIG. 48. FIG. 42 to FIG. 47 are explanatory drawings of the molding process in the second embodiment, and FIG. 48 is a perspective view illustrating the board substrate 1 that is released from the mold after the steps in FIG. 42 to FIG. 47.

First, the steps described referring to FIG. 1 to FIG. 6 are carried out, and thereafter, the lower face of the movable cavity piece 8C is set to a level lower than the bottom face of the recess in the upper die cavity 8B1, as illustrated in FIG. 42. That is, the lower part of the movable cavity piece 8C is protruded to the cavity side. Subsequently, similarly with the first embodiment, the board substrate 1 is clamped and held between the upper die 8B and the lower die 8A, as illustrated in FIG. 43, and thereby the cavity CB is formed. Subsequently, similarly with the first embodiment, the above-mentioned sealing resin is poured into the cavity CB, as illustrated in FIG. 44. Thereby, a plurality of the chips 6, bonding wires 7, and the like on the principal surface of the board substrate 1 are sealed in a lump. Thus, the blanket sealing body 9 containing a plurality of the chips 6 on the principal surface side of the board substrate 1 is molded.

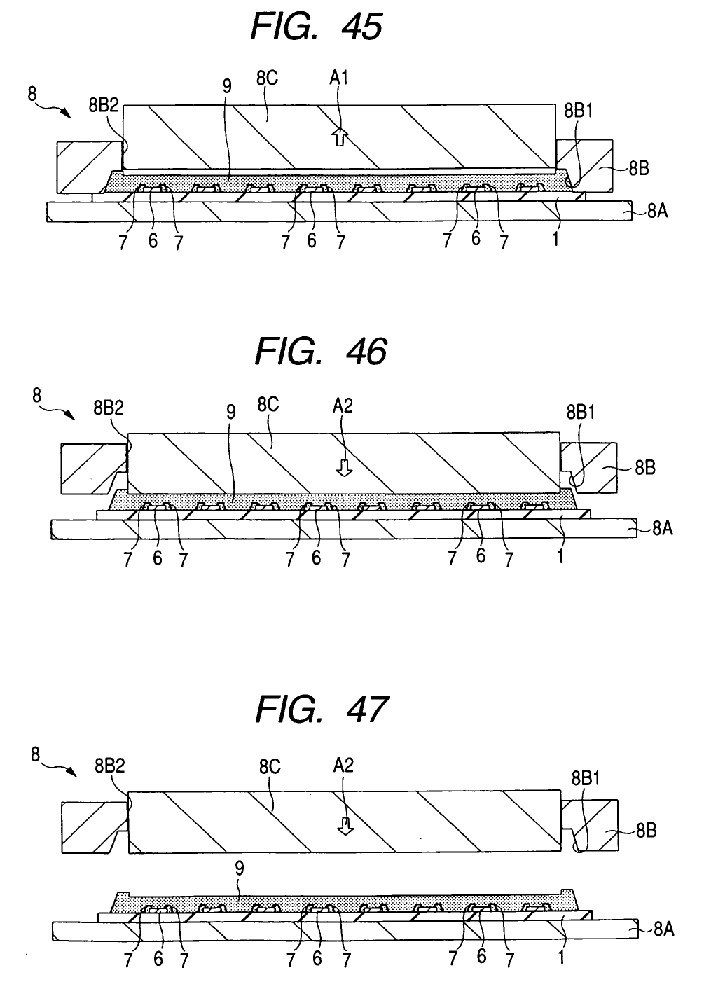

Following the completion of curing of the sealing resin, mold release is carried out. At this time, similarly with the first embodiment, first, the movable cavity piece 8C is moved up in the direction indicated by arrow A1, as illustrated in FIG. 45. Thereby, the lower face of the movable cavity piece 8C is broken away from the blanket sealing body 9. At this time again, similarly with the first embodiment, the upper die 8B firmly holds down the peripheral portion of the element placement face of the board substrate 1 and the peripheral portion (shoulder) 9a of the blanket sealing body 9 in a balanced manner. Therefore, the movable cavity piece 8C can be easily broken away from the blanket sealing body 9 without damaging the blanket sealing body 9. Further, since force for mold release is not applied directly to the chips 6, chip crack failure can be prevented, and the yield and reliability of semiconductor devices can be enhanced. Subsequently, similarly with the first embodiment, the lower die 8A and the upper die 8B are separated from each other, as illustrated in FIG. 46. At the same time, the movable cavity piece 8C is pressed down in the direction indicated by arrow A2 to push the board substrate 1 out of the upper die cavity 8B1. Thus, the board substrate 1 is released from the upper die 8B, as illustrated in FIG. 47. FIG. 48 illustrates an example of a perspective view of the board substrate 1 after the above-mentioned mold release. The general plan view of the board substrate 1 on the element placement face side in FIG. 48 is the same as in FIG. 14. In this example, a recessed portion 9c is formed inside the peripheral portion 9a of the upper face of the blanket sealing body 9. The recessed portion 9c is recessed to a level lower than the peripheral portion 9a. The size of the flat face of the recessed portion 9c is the same as that of the upper face of the projected portion 9b.

In the second embodiment as well, the same effects as in the first embodiment can be obtained.

Up to this point, the invention made by the present inventors has been specifically described based on the embodiments. However, the present invention is not limited to these embodiments, and various changes may be made to the present invention without departing from the scope of the invention, needless to add.

Some examples will be taken. In the description of the first and second embodiments, the present invention is applied to the MAP method of manufacturing semiconductor devices. However, the present invention is not limited to this constitution, and is applicable to common molding processes wherein individual areas are molded with sealing resin.

In the description of the first embodiment, the projected portion 9b is formed on the upper face of the blanket sealing body 9, and in the description of the second embodiment, the recessed portion 9c is formed in the upper face of the blanket sealing body. However, the upper face of the blanket sealing body 9 may be flat without a step. This is accomplished by adjusting the amount of movement so that the position of the lower face of the movable cavity piece 8C will be matched with the position of the bottom face of the recess of the upper die cavity 8B1.

Up to this point, description has been given mainly to cases where the invention made by the present inventors is applied to a method of manufacturing semiconductor devices, which is a field of utilization underlying the invention. However, the present invention is not limited to these constitutions, and various changes may be made to the present invention. For example, the present invention is applicable to resin molding methods for other products, such as multichip packages wherein a plurality of chips are sealed in individual semiconductor devices.

The embodiments disclosed above relate to methods which do not use laminate films. However, such a method that a blanket sealing body 9 is released from a mold using a laminate film placed between the cavity face of the mold 8 and the blanket sealing body 9 may be adopted.

The present invention is applicable to the manufacturing industries for semiconductor devices.

1. A method of manufacturing a semiconductor device, comprising the steps of:
(a) preparing a substrate;
(b) mounting semiconductor chips over the substrate;
(c) placing the substrate, over which the semiconductor chips are mounted, over the molding surface of the lower die of a mold;
(d) clamping and holding the substrate between the lower die and the upper die of the mold;
(e) filling the cavity in the mold with sealing resin to form a sealing body; and
(f) releasing the substrate from the mold after the step (e),
wherein the upper die has an opening which runs from the outside surface of the upper die to the cavity, and a movable block fit into the opening so that the movable block is movable in the direction intersecting the molding surface of the upper die, and
wherein the size of the lower face of the movable block is equal to or larger than the size of the product area of the substrate and smaller than the size of the upper face of the cavity.

2. The method of manufacturing a semiconductor device according to claim 1,
wherein a projected portion is formed inside the peripheral portion of the upper face of the sealing body.

3. The method of manufacturing a semiconductor device according to claim 1,
wherein a recessed portion is formed inside the peripheral portion of the upper face of the sealing body.

4. The method of manufacturing a semiconductor device according to claim 1,
wherein blocks for adjusting an amount of movement of the movable block are detachably provided outside the cavity in the mold.

5. The method of manufacturing a semiconductor device according to claim 1,
wherein the step (f) includes the steps of moving up the movable block with the peripheral portion of the product area of the sealing body and the substrate being clamped between the upper die and the lower die, and separating the movable block from the sealing body.

6. The method of manufacturing a semiconductor device according to claim 1, comprising a step of:
prior to the step (e) , adjusting the amount of movement of the movable block in accordance with a thickness demanded of the sealing body.

7. A method of manufacturing a semiconductor device, comprising the steps of:
(a) preparing a substrate having a product area in which a plurality of unit product areas are disposed;
(b) mounting a semiconductor chip in each of a plurality of the unit product areas;
(c) placing the substrate, over which a plurality of the semiconductor chips are mounted, over the molding surface of the lower die of a mold;
(d) clamping and holding the substrate between the lower die and the upper die of the mold;
(e) filling the cavity in the mold with sealing resin to form a blanket sealing body which seals a plurality of the semiconductor chips in the product area in a lump; and
(f) releasing the substrate from the mold after the step (e),
wherein the upper die has an opening which runs from the outside surface of the upper die to the cavity, and a movable-block fit into the opening so that the movable block is movable in the direction intersecting the molding surface of the upper die, and
wherein the size of the lower face of the movable block is equal to or larger than the size of the product area of the substrate and smaller than the size of the upper face of the cavity.

8. The method of manufacturing a semiconductor device according to claim 7,
wherein a projected portion is formed inside the peripheral portion of the upper face of the blanket sealing body.

9. The method of manufacturing a semiconductor device according to claim 7,
wherein a recessed portion is formed inside the peripheral portion of the upper face of the blanket sealing body.

10. The method of manufacturing a semiconductor device according to claim 7,
wherein blocks for adjusting the amount of movement of the movable block are detachably provided outside the cavity in the mold.

11. The method of manufacturing a semiconductor device according to claim 7, comprising a step of:
after the step (f), cutting the blanket sealing body and the substrate into a plurality of the unit product areas.

12. The method of manufacturing a semiconductor device according to claim 7, comprising a step of:
after the step (f), forming bump electrodes over the rear face of the substrate and then cutting the blanket sealing body and the substrate into a plurality of the unit product areas.

13. The method of manufacturing a semiconductor device according to claim 7,
wherein the step (f) includes the steps of moving up the movable block with the peripheral portion of the product area of the blanket sealing body and the substrate being clamped between the upper die and the lower die, and separating the movable block from the blanket sealing body.

14. The method of manufacturing a semiconductor device according to claim 7, comprising a step of:
prior to the step (e), adjusting the amount of movement of the movable block in accordance with a thickness demanded of the blanket sealing body in the product area.
